(19) United States
(12) Patent Application Publication
(10) Pub. No.: US 2026/0130237 A1
(43) Pub. Date: May 7, 2026

(54) FILM PACKAGE, SEMICONDUCTOR MODULE AND DISPLAY DEVICE INCLUDING THE SAME, AND MANUFACTURING METHOD OF FILM PACKAGE

(71) Applicant: Samsung Electronics Co., Ltd., Suwon-si (KR)

(72) Inventors: Seunghyun Cho, Suwon-si (KR); JAE-MIN JUNG, Suwon-si (KR); Minwoo Cho, Suwon-si (KR); JEONG-KYU HA, Suwon-si (KR)

(21) Appl. No.: 19/223,367

(22) Filed: May 30, 2025

(30) Foreign Application Priority Data
Nov. 7, 2024 (KR) 10-2024-0157075

(51) Int. Cl. H01L 23/495; H01L 23/00

(52) U.S. Cl. CPC H10W 70/461; H10W 70/453; H10W 90/811; H10W 74/15; H10W 90/724; H10W 90/734

(57) ABSTRACT

A semiconductor module including a film package, and a printed circuit board connected to a first surface of the film package. The film package includes a base film, a semiconductor chip on the first surface of the base film, and a first conductive pattern on the first surface of the base film. The first conductive pattern includes a first circuit pattern and a first dummy pattern. The first dummy pattern is spaced apart from the first circuit pattern and is between the first surface of the base film and the printed circuit board.

### CROSS-REFERENCE TO RELATED APPLICATION

This application claims priority under 35 U.S.C. § 119 to and the benefit of Korean Patent Application No. 10-2024-0157075 filed in the Korean Intellectual Property Office on Nov. 7, 2024, the entire contents of which are incorporated herein by reference.

### BACKGROUND

### (a) Field

The present disclosure relates to a film package, a semiconductor module and a display device including the same, and a manufacturing method of a film package.

### (b) Description of the Related Art

A semiconductor device may have a small size while performing various functions, and is thus widely used in various electronic industries. As advancements are made in the electronic industry, research is continuing on a packaging technology being capable of reducing a size of a semiconductor device while increasing performance of the semiconductor device.

If a large amount of heat is generated in a semiconductor chip included in a film package, performance of the semiconductor chip may be deteriorated or the semiconductor chip may malfunction. Accordingly, research is continuing on a film package being capable of effectively dissipating the heat generated in the semiconductor chip.

### SUMMARY

The present disclosure attempts to provide a film package capable of enhancing performance, a semiconductor module and a display device including the same, and a manufacturing method of a film package capable of enhancing performance and productivity.

A semiconductor module according to an embodiment includes a film package, and a printed circuit board connected to a first surface of the film package. The film package includes a base film, a semiconductor chip on the first surface of the base film, and a first conductive pattern on the first surface of the base film. The first conductive pattern includes a first circuit pattern and a first dummy pattern. The first dummy pattern is spaced apart from the first circuit pattern and is between the first surface of the base film and the printed circuit board.

A display device according to an embodiment includes a film package, a printed circuit board connected to the film package, and a display panel connected to the film package. The film package includes a base film, a semiconductor chip on a first surface of the base film facing the printed circuit board or the display panel, and a first conductive pattern on the first surface of the base film. The first conductive pattern includes a first circuit pattern and a first dummy pattern. The first dummy pattern is spaced apart from the first circuit pattern and is between the first surface of the base film and the printed circuit board.

A film package according to an embodiment includes a base film, a semiconductor chip on a first surface of the base film, and a first conductive pattern on the first surface of the base film. The first conductive pattern includes a first circuit pattern and a first dummy pattern. The first circuit pattern is in a circuit region. The first circuit pattern includes a first outer terminal at a first end of the circuit region in a first direction and a second outer terminal at a second opposite end of the circuit region in the first direction. The first dummy pattern is in a dummy region outside the circuit region in the first direction and is electrically isolated from the first circuit pattern and the semiconductor chip.

A manufacturing method of a film package according to an embodiment includes forming a first photoresist pattern on a first surface of a base film, forming a first metal layer in an area other than area that includes the first photoresist pattern on the first surface of the base film, and removing the first photoresist pattern. The first photoresist pattern exposes areas of the first surface of the base film where a first circuit pattern and a first heat dissipation pattern are disposed. The first metal layer includes at least a portion of the first circuit pattern and the first heat dissipation pattern.

A manufacturing method of a film package according to an embodiment includes forming a first photoresist pattern on a first surface of a base film, wherein the first photoresist pattern exposes areas of the first surface of the base film where a first circuit pattern and a first heat dissipation pattern are disposed; forming a first metal layer in an area other than an area that includes the first photoresist pattern on the first surface of the base film, wherein the first metal layer includes at least a portion of the first circuit pattern and the first heat dissipation pattern; and removing the first photoresist pattern.

The method further includes forming a second heat dissipation pattern on a second surface of the base film opposite to the first surface of the base film.

The method includes forming a second photoresist pattern on the second surface of the base film, wherein the second photoresist pattern exposes at least an area where a second heat dissipation pattern is disposed; forming a second metal layer in an area other than an area including the second photoresist pattern on the second surface of the base film, wherein the second metal layer includes at least a portion of the second heat dissipation pattern; and removing the second photoresist pattern.

The method further includes: forming a through hole in an area of the base film where the first heat dissipation pattern and the second heat dissipation pattern overlap each other, before the forming of the first photoresist pattern. In at least one of the forming of the first metal layer and the forming of the second metal layer, the through hole is filled to form a through connector that connects the first heat dissipation pattern and the second heat dissipation pattern.

At least a part of the forming of the first photoresist pattern and at least a part of the forming of the second photoresist pattern are performed at the same time; or the forming of the first metal layer and the forming of the second metal layer are performed at the same time; or the removing of the first photoresist pattern and the removing of the second photoresist pattern are performed at the same time.

The method further includes: forming a seed layer on the base film, before the forming of the first photoresist pattern, and removing a portion of the seed layer where the first metal layer is not disposed, after the removing of the first photoresist pattern.

The first photoresist pattern includes a dry film including a photoresist material.

The first circuit pattern is disposed in a circuit region and includes a first outer terminal and a second outer terminal at opposite ends of the circuit region in a first direction, and the first heat dissipation pattern is in a dummy region disposed outside the circuit region in the first direction and is spaced apart from the first circuit pattern.

The first heat dissipation pattern is disposed outside of a first end of the circuit region that is adjacent to the first outer terminal in the first direction, and a line width, a pitch, or an interval of the first outer terminal is greater than a line width, a pitch, or an interval of the second outer terminal.

The method further includes, after the removing of the first photoresist pattern: forming a first protective layer on the first surface of the base film, wherein the first protective layer covers at least a portion of the first circuit pattern and exposes a chip region; and mounting a semiconductor chip to be electrically connected to a portion of the first circuit pattern exposed in the chip region.

A semiconductor module according to an embodiment includes: a flexible film having a first surface and a second surface opposite to the first surface; a semiconductor chip disposed on the first surface of the flexible film; a printed circuit board disposed on the first surface of the flexible film; a circuit pattern disposed on the first surface of the flexible film and electrically connected to the semiconductor chip and the printed circuit board; a first dummy pattern disposed on the first surface of the flexible film and physically connected to the printed circuit board; a second dummy pattern disposed on the second surface of the flexible film; and a dummy through connector penetrating the flexible film and physically connected to the first dummy pattern and the second dummy pattern. The first dummy pattern, the second dummy pattern, and the dummy through connector are included in a heat dissipation path and are electrically isolated from any circuitry of at least one of the printed circuit board and the semiconductor chip.

According to an embodiment, a film package may include a first dummy pattern connected to a printed circuit board and may have a heat dissipation path to the printed circuit board. The film package may further include a second dummy pattern having a relatively large area and a through connector that connects the first dummy pattern and the second dummy pattern. Thereby, a heat dissipation property of the film package may be enhanced, and performance of the film package may be enhanced.

In a process of forming a circuit pattern, a dummy pattern may be formed together. Therefore, a manufacturing process of a film package including the dummy pattern may be simplified and a shape or arrangement freedom of the dummy pattern may be enhanced. Further, a thickness and weight of the film package may be reduced. Accordingly, performance and productivity of the film package may be enhanced.

### BRIEF DESCRIPTION OF THE DRAWINGS

FIG. 1 is a rear perspective view that schematically illustrates an example of a display device including a semiconductor module according to embodiment.

FIG. 2 is a schematic cross-sectional view of the display device illustrated in FIG. 1.

FIG. 3 is a cross-sectional view of the semiconductor module that is included in the display device illustrated in FIG. 1.

FIG. 4 is a top plan view of a film package that is included in the display device illustrated in FIG. 1.

FIG. 5 is a rear plan view of the film package that is included in the display device illustrated in FIG. 1.

FIG. 6 is a rear plan view of a film package of a reel shape that includes a plurality of film packages according to embodiment.

FIG. 7 to FIG. 14 are cross-sectional views that illustrate a manufacturing method of a film package according to an embodiment.

FIG. 15 is a rear plan view that illustrates a film package according to an embodiment.

FIG. 16 is a rear plan view that illustrates a film package according to an embodiment.

FIG. 17 is a rear plan view that illustrates a film package according to an embodiment.

FIG. 18 is a rear plan view that illustrates a film package according to an embodiment.

FIG. 19 is a cross-sectional view that illustrates a semiconductor module according to an embodiment.

FIG. 20 is a cross-sectional view that illustrates a semiconductor module according to an embodiment.

FIG. 21 is a cross-sectional view that illustrates a semiconductor module according to an embodiment.

### DETAILED DESCRIPTION

Embodiments of the present disclosure will be described more fully hereinafter with reference to the accompanying drawings for those skilled in the art to which the present disclosure pertains to easily practice the present disclosure. The present disclosure may be implemented in various different forms and is not limited to the embodiments provided herein.

A portion unrelated to the description is omitted in order to clearly describe the present disclosure, and same or similar components are denoted by the same reference numeral throughout the present specification.

Further, since sizes and thicknesses of portions, regions, members, units, layers, films, or the like., illustrated in the accompanying drawings may be arbitrarily illustrated for better understanding and convenience of explanation, the present disclosure is not limited to the illustrated sizes and thicknesses. In the drawings, thicknesses of portions, regions, members, units, layers, films, or the like., may be enlarged or exaggerated for convenience of explanation and/or simple illustration.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting,” “in contact with,” or “contact” another element, there are no intervening elements present at the point of contact. Further, when a component is referred to as being “on” or “above” a reference component, a component may be positioned on or below the reference component, and may not necessarily be “on” or “above” the reference component toward an opposite direction of gravity.

In addition, unless explicitly described to the contrary, the word “comprise”, “include”, or “contain”, and variations such as “comprises”, “comprising”, “includes”, “including”, “contains” or “containing” will be understood to imply the inclusion of other components rather than the exclusion of any other components.

Further, throughout the specification, a phrase “on a plane”, “in a plane”, “on a plan view”, or “in a plan view” may indicate a case where a portion is viewed from above or a top portion, and a phrase “on a cross-section” or “in a cross-sectional view” may indicate a vertical cross-sectional viewed from a side.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

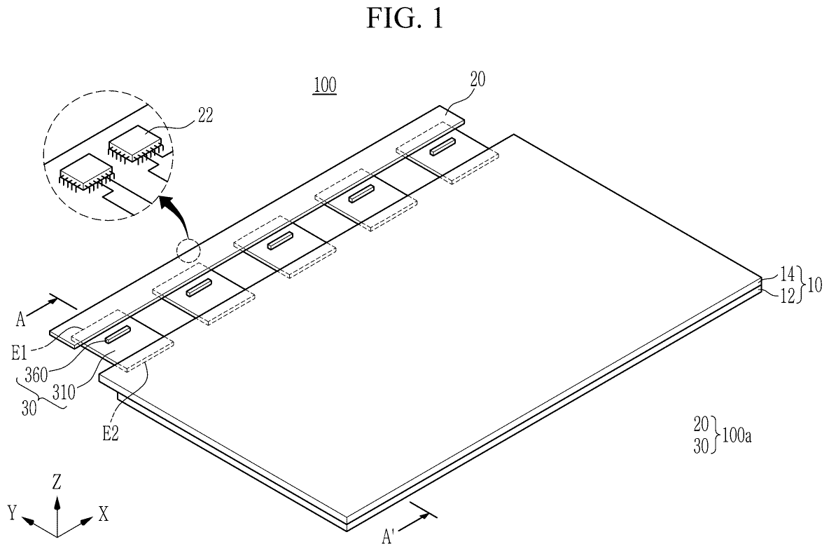

Hereinafter, referring to FIG. 1 to FIG. 14, a film package 30 according to an embodiment, a semiconductor module 100a and a display device 100 including the same, and a manufacturing method of a film package 30 will be described in detail.

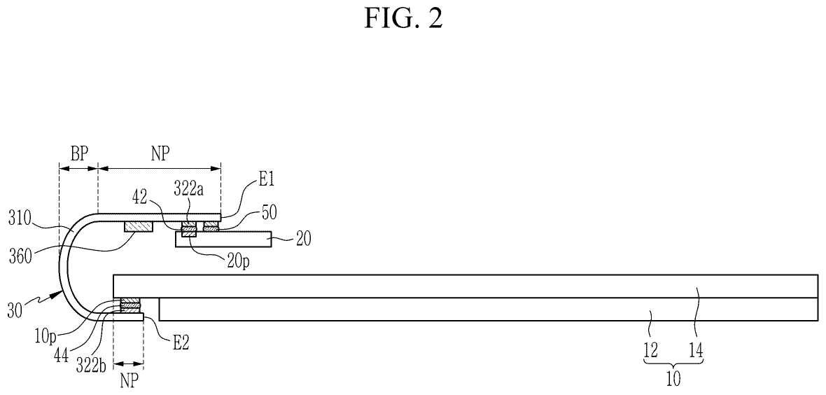

FIG. 1 is a rear perspective view that schematically illustrates an example of a display device 100 including a semiconductor module 100a according to embodiment. FIG. 2 is a schematic cross-sectional view of the display device 100 illustrated in FIG. 1.

For a clear understanding, a display panel 10, a printed circuit board 20, and a film package 30 are mainly illustrated in FIG. 1 and FIG. 2, and coordinates in the drawings are based on the film package 30 of an unfolded state. In FIG. 1, a rear surface of the display device 100 and a front surface (or a top surface) of the film package 30 where a semiconductor chip 360 is disposed are disposed in a positive Z-axis direction, and a front surface of the display device 100 and a rear surface of the film package 30 opposite to the front surface of the film package 30 are disposed in a negative Z-axis direction. FIG. 1 illustrates the display device 100 where the film package 30 is unfolded, and FIG. 2 illustrates the display device 100 where the film package 30 is folded, taken along a line A-A′ in FIG. 1.

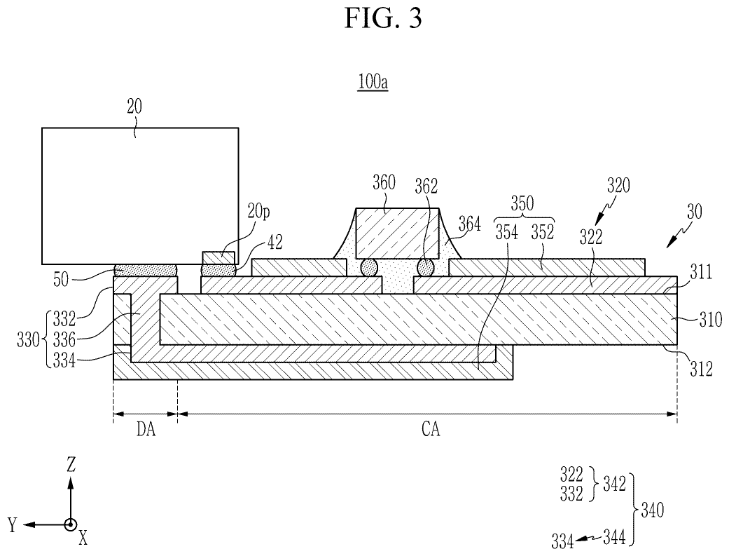

Referring to FIG. 1 and FIG. 2, a display device 100 according to an embodiment may include a display panel 10, a printed circuit board 20, and a film package 30 that connects the display panel 10 and the printed circuit board 20. The printed circuit board 20 may be connected to a first edge E1 of the film package 30, and the display panel 10 may be connected to a second edge E2 of the film package 30. The printed circuit board 20 and the film package 30 may be referred to as the semiconductor module 100a (refer to FIG. 3).

The display device 100 according to an embodiment may be included in any of various devices. For example, the display device 100 may be included in at least one of electronic devices in vehicles, home appliances, televisions, mobile phones, personal computers, tablets, e-book readers, desktop PCs, personal digital assistants (PDA), cameras, servers, mobile medical devices, wearable devices, security devices, or internet of things (IoT). However, the embodiments are not limited thereto.

The display panel 10 may include any of various panels capable of displaying images. For example, the display panel 10 may include a liquid crystal display (LCD), a light emitting diode (LED) display, an organic light emitting diode (OLED) display, a plasma display panel (PDP), or the like. However, the embodiments are not limited thereto, and the display panel 10 may have any of various structures or types.

A circuit element 22 may be mounted on the printed circuit board 20. The circuit element 22 may be configured to provide electrical signals to the display panel 10 and/or the semiconductor chip 360 of the film package 30.

The film package 30 may physically and electrically connect the display panel 10 and the printed circuit board 20. The film package 30 may include a base film 310, and the semiconductor chip 360 disposed on the base film 310.

The semiconductor chip 360 may include an integrated circuit (IC). For example, the semiconductor chip 360 may include a display driver integrated circuit (DDIC). The semiconductor chip 360 may include a power supply portion, a logic circuit portion, a memory portion, an interface, or the like. The semiconductor chip 360 may include an active element (e.g., a transistor, a pn junction diode, a Schottky barrier diode, or the like) and/or a passive element (e.g., a capacitor, a resistor, an inductor, or the like).

In an embodiment, the film package 30 that includes the semiconductor chip 360 (e.g., the display driver integrated circuit) may be separately provided from the display panel 10 and the printed circuit board 20 and may connect the display panel 10 and the printed circuit board 20, but the embodiments are not limited thereto. The film package 30 that includes the semiconductor chip 360 (e.g., the display driver integrated circuit) may be a portion of the display panel 10, and the printed circuit board 20 may be connected to the film package 30 that is the portion of the display panel 10. Various other modified embodiments are possible.

The printed circuit board 20 may face one edge of the display panel 10.

The film package 30 that connects the display panel 10 and the printed circuit board 20 may be referred to as a chip on film (COF), a tape package, a chip package, a semiconductor package, a connecting member, or the like.

The film package 30 may be disposed to connect one edge of the display panel 10 and one edge of the printed circuit board 20 that is adjacent thereto. For example, the film package 30 may extend in a first direction (a Y-axis direction in the drawings) that intersects (e.g. is perpendicular to) one edge of the display panel 10 and one edge of the printed circuit board 20. A plurality of film packages 30 may be disposed to have regular intervals in a second direction (an X-axis direction in the drawings) that is parallel to one edge of the display panel 10 or one edge of the printed circuit board 20. The X-axis direction, the Y-axis direction, and a third direction (Z-axis direction in the drawings) may be respectively referred to as a first horizontal direction, a second horizontal direction, and a vertical direction.

The film package 30 may electrically connect the display panel 10 and the printed circuit board 20. More particularly, a first outer terminal 322a may be disposed near the first edge E1 of the film package 30 that is adjacent to the printed circuit board 20, and may be electrically connected to a second pad 20p of the printed circuit board 20. A second outer terminal 322b may be disposed near the second edge E2 of the film package 30 that is adjacent to the display panel 10, and may be electrically connected to a first pad 10p of the display panel 10. The first outer terminal 322a and the second outer terminal 322b will be described in more detail with reference to FIG. 3 to FIG. 5. Additionally, as further detailed below, the first outer terminal 322a, the second outer terminal 322b, and a wiring 322c may collectively constitute a first circuit pattern 322.

In an embodiment, a first conductive adhesive layer 42 may be disposed between the first outer terminal 322a of the film package 30 and the pad 20p of the printed circuit board 20 and physically and electrically connect the film package 30 and the printed circuit board 20. A second conductive adhesive layer 44 may be disposed between the second outer terminal 322b of the film package 30 and the pad 10p of the display panel 10 and physically and electrically connect the film package 30 and the display panel 10. For example, the first conductive adhesive layer 42 or the second conductive adhesive layer 44 may be an anisotropic conductive film (ACF). However, the embodiments are not limited thereto, and a connection structure of the film package 30 and the printed circuit board 20, or a connection structure of the film package 30 and the display panel 10 may be variously modified.

In FIG. 1, it is illustrated as an example that one printed circuit board 20 is disposed to correspond to one edge of the display panel 10. However, the embodiments are not limited thereto, and a plurality of printed circuit boards 20 may be disposed to correspond to one edge of the display panel 10. In FIG. 1, it is illustrated as an example that the film package 30 and the printed circuit board 20 are disposed at one edge of the display panel 10. However, the embodiments are not limited thereto, and the film package 30 and the printed circuit board 20 may be disposed at a plurality of edges of the display panel 10.

The circuit element 22 of the printed circuit board 20 may include a driving circuit configured to process image signals, and the driving circuit may generate control signals configured to display images on the display panel 10. The semiconductor chip 360 of the film package 30 may change the control signals transmitted through the first outer terminal 322a into pixel signals provided to pixels, respectively, and the pixel signals may be transmitted to the display panel 10 through the second outer terminal 322b of the film package 30. According to the pixel signals, the display panel 10 may display images.

The film package 30 according to an embodiment may be bonded to a front surface of the display panel 10. For example, the display panel 10 may include a front substrate 12 and a rear substrate 14. The pad 10p of the display panel 10 may be disposed on a front surface of the rear substrate 14 exposed outside the front substrate 12, and the second outer terminal 322b of the film package 30 may be bonded to the pad 10p of the display panel 10 that is disposed on the front surface of the rear substrate 14. However, the embodiments are not limited thereto, and a position of the pad 10p of the display panel 10, a bonding position of the film package 30, or the like may be variously modified.

As illustrated in FIG. 2, a portion of the film package 30 that is bonded to the front surface of the display panel 10 may be folded, and at least a portion of the film package 30 may be disposed at a rear surface of the display panel 10 in a folded state. For example, the film package 30 may include a front portion, a rear portion, and a side portion. The front portion may be disposed at the front surface of the display panel 10, the rear portion may be disposed at the rear surface of the display panel 10, and the side portion may be disposed at a side surface of the display panel 10 and be folded and connected to the front portion and the rear portion. The front portion and the rear portion may be an unfolded portion NP where the film package 30 is not folded or bent, and the side portion may be a folded portion BP where the film package 30 is folded or bent.

Since the film package 30 may include the folded portion BP, the display panel 10 and the printed circuit board 20 may be connected in three-dimensions. Accordingly, design freedom of the display device 100 may be enhanced and a space of the display device 100 may be reduced.

Referring to FIG. 3 to FIG. 5 together with FIG. 1 and FIG. 2, the film package 30 according to embodiment and the semiconductor module 100a including the same will be described in more detail.

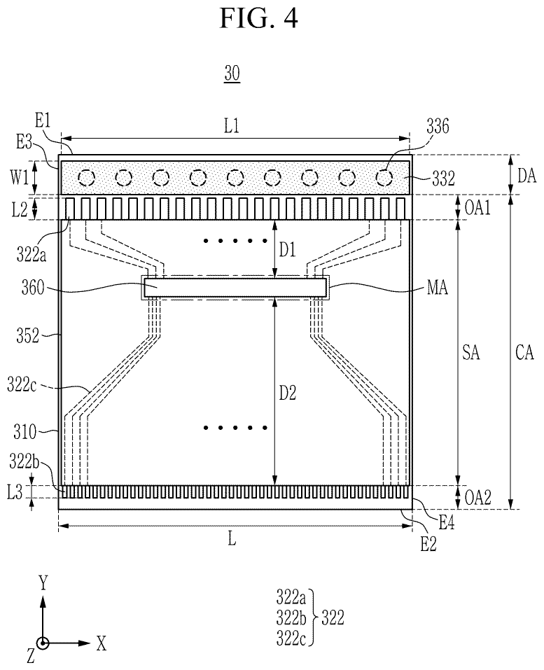

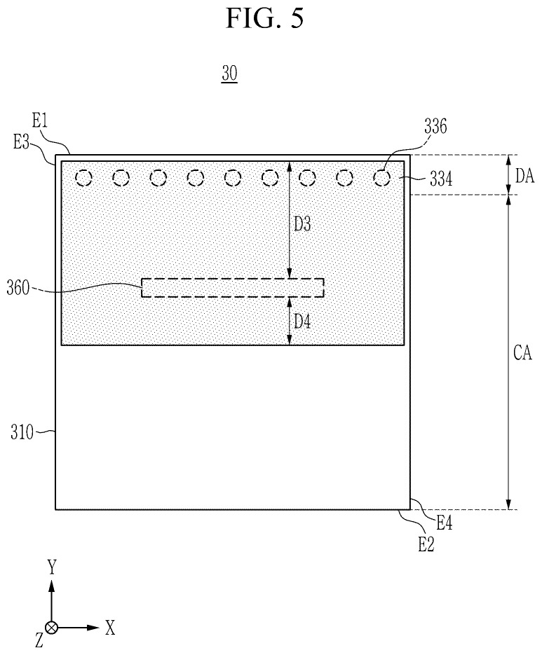

FIG. 3 is a cross-sectional view of the semiconductor module 100a that is included in the display device 100 illustrated in FIG. 1. FIG. 3 illustrates the semiconductor module 100a where the film package 30 is unfolded, taken along the line A-A′ in FIG. 1. FIG. 4 is a top plan view of the film package 30 that is included in the display device 100 illustrated in FIG. 1. FIG. 5 is a rear plan view of the film package 30 that is included in the display device 100 illustrated in FIG. 1. For a clear understanding and simple illustration, in FIG. 5, a second protective layer 354 that is disposed at a rear surface of the film package 30 is omitted.

Referring to FIG. 1 to FIG. 5, the film package 30 that is included in the semiconductor module 100a according to embodiment may include a base film 310, and a conductive pattern 340 and a semiconductor chip 360 that are disposed on the base film 310. The conductive pattern 340 may include a circuit pattern 320 and a separated pattern 330. A protective layer 350 may be further included. The protective layer 350 may cover at least a portion of the circuit pattern 320 that is disposed on the base film 310.

The film package 30 (e.g., the base film 310) may include a first edge E1, a second edge E2, a third edge E3, and a fourth edge E4. The first edge E1 and the second edge E2 may be opposite to each other in a first direction (a Y-axis direction in the drawings), and the third edge E3 and the fourth edge E4 may be opposite to each other in a second direction (an X-axis direction in the drawings). The first edge E1 of the film package 30 (e.g., the base film 310) may be an edge adjacent to the printed circuit board 20 or the first outer terminal 322a in the first direction, and the second edge E2 of the film package 30 (e.g., the base film 310) may be an edge adjacent to the display panel 10 or the second outer terminal 322b in the first direction.

The base film 310 may include a first surface 311 and a second surface 312 opposite to each other. The first surface 311 of the base film 310 may be a facing surface that faces the printed circuit board 20 and/or the display panel 10, and the second surface 312 of the base film 310 may be an opposite surface that is opposite to the first surface 311 of the base film 310.

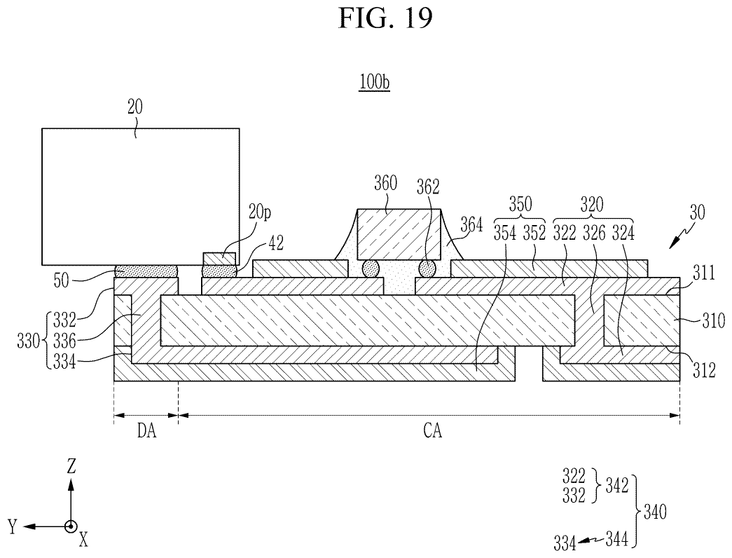

In an embodiment, the circuit pattern 320 may include a first circuit pattern 322 that is disposed on the first surface 311 of the base film 310 and/or a second circuit pattern that is disposed on the second surface 312 of the base film 310. In FIG. 3, it is illustrated as an example that the circuit pattern 320 includes the first circuit pattern 322 and does not include the second circuit pattern. An embodiment where a circuit pattern 320 includes a first circuit pattern 322 and a second circuit pattern 324 will be described later with reference to FIG. 19.

In an embodiment, the separated pattern 330 may include a first separated pattern 332 and/or a second separated pattern 334. The first separated pattern 332 may be disposed on the first surface 311 of the base film 310, and the second separated pattern 334 may be disposed on the second surface 312 of the base film 310. The separated pattern 330 may further include a through connector 336. The through connector 336 may penetrate or pass through the base film 310 and connect (e.g., directly connect) the first separated pattern 332 and the second separated pattern 334.

In an embodiment, the conductive pattern 340 may include a first conductive pattern 342 and a second conductive pattern 344. The first conductive pattern 342 may be disposed on the first surface 311 of the base film 310, and the second conductive pattern 344 may be disposed on the second surface 312 of the base film 310. The first conductive pattern 342 may include the first circuit pattern 322 and the first separated pattern 332, and the second conductive pattern 344 may include the second circuit pattern and/or the second separated pattern 334. The conductive pattern 340 may include or may be formed of metal, and may be referred to as a metal pattern.

The protective layer 350 may include a first protective layer 352, and further include a second protective layer 354. The first protective layer 352 may be disposed on the first circuit pattern 322 on the first surface 311 of the base film 310, and the second protective layer 354 may be disposed on the second circuit pattern and/or the second separated pattern 334 on the second surface 312 of the base film 310.

The base film 310 may mechanically support the conductive pattern 340 and the protective layer 350 that are disposed on the base film 310. In an embodiment, the base film 310 may mechanically support the first circuit pattern 322, the first separated pattern 332, and the first protective layer 352 that are disposed on the first surface 311 of the base film 310, and mechanically support the second separated pattern 334 and the second protective layer 354 that are disposed on the second surface 312 of the base film 310.

The base film 310 may be a flexible film or a flexible substrate. At least a portion of the flexible film or the flexible substrate may be bent or folded. The base film 310 may include or may be formed of an insulating material (e.g., a polymer material). For example, the base film 310 may include or may be formed of at least one of polyimide (PI), polyethylene terephthalate (PET), or polyethylene naphthalate (PEN). However, the embodiments are not limited thereto, and the base film 310 may include any of various insulating materials.

The base film 310 may have a thickness of 5 μm to 100 μm. For example, the base film 310 may have a thickness of 10 μm to 90 μm. For example, the base film 310 may have a thickness of 12 μm to 80 μm. If the thickness of the base film 310 is greater than 100 μm, a thickness of the film package 30 may increase. If the thickness of the base film 310 is less than 5 μm, the base film 310 may be vulnerable to heat, pressure, or the like. However, the embodiments are not limited thereto, and the thickness of the base film 310 may be less than 5 μm, or be greater than 100 μm.

In a plan view, as illustrated for example in FIG. 4, the film package 30 (e.g., the base film 310) may include a circuit region CA, and a dummy region DA outside the circuit region CA. In the circuit region CA, the first circuit pattern 322 and the semiconductor chip 360 may be disposed. The dummy region DA may be a region other than the circuit region CA and/or a region in which the first separated pattern 332 is disposed.

The circuit region CA may include a chip region MA, a cover region SA, a first terminal region OA1, and a second terminal region OA2. In the chip region MA, the semiconductor chip 360 may be disposed. The cover region SA may be disposed at a periphery of the chip region MA and be covered by the first protective layer 352. The first terminal region OA1 may be disposed at a first side of the cover region SA in the first direction (the Y-axis direction in the drawings), and the second terminal region OA2 may be disposed at a second side of the cover region SA opposite to the first side of the cover region SA in the first direction. The first terminal region OA1 may be disposed outside the cover region SA. For example, in the first direction (the Y-axis direction in the drawings), the first terminal region OA1 may be disposed between the cover region SA and the dummy region DA. The second terminal region OA2 may be disposed outside the cover region SA. For example, in the first direction (the Y-axis direction in the drawings), the second terminal region OA2 may be disposed adjacent to the second edge E2. The first outer terminal 322a may be disposed in the first terminal region OA1, and the second outer terminal 322b may be disposed in the second terminal region OA2. In the first direction, the first outer terminal 322a or the first terminal region OA1 may be disposed near the first edge E1 of the film package 30, and the second outer terminal 322b or the second terminal region OA2 may be disposed near the second edge E2 of the film package 30 opposite to the first edge E1.

The dummy region DA may be disposed outside a first side (an upper side in FIG. 4) of the circuit region CA in the first direction (the Y-axis direction in the drawings), and may have a shape extending in the second direction (the X-axis direction in the drawings). For example, the dummy region DA may be disposed between the circuit region CA and the first edge E1 of the film package 30 in the first direction. The dummy region DA may not be disposed outside a second side (a lower side in FIG. 4) of the circuit region CA opposite to the first side of the circuit region CA in the first direction. For example, the dummy region DA may be disposed near the first edge E1 of the film package 30 and may not be disposed near the second edge E2 of the film package 30. Accordingly, the dummy region DA may have an asymmetrical shape in the first direction. Conductive patterns 340 disposed in or extending from the dummy region DA do not transfer electrical signals to conductive patterns 340 in the circuit region CA. For example, according to some embodiments, separated pattern 330 (including first separated pattern 332, second separated pattern 334, and through connector 336) is not electrically connected to the semiconductor chip 360 and/or the printed circuit board 20. According to some embodiments, the separated pattern 330 (including first separated pattern 332, second separated pattern 334, and through connector 336) is electrically insulated (e.g., electrically isolated) from the first circuit pattern 322, and the semiconductor chip 360 and/or the printed circuit board 20. According to some embodiments, the separated pattern 330 (including first separated pattern 332, second separated pattern 334, and through connector 336) is electrically insulated (e.g., electrically isolated) from the first circuit pattern 322, and any circuitry included the semiconductor chip 360 and/or any circuitry included in the printed circuit board 20. As such, the separated pattern 330 (including first separated pattern 332, second separated pattern 334, and through connector 336) may be referred to as “dummy patterns” or “heat dissipation patterns” as they do not transfer electrical signals or data signals from or to the semiconductor chip 360 and/or the printed circuit board 20. For example, the first separated pattern 332 may be a first dummy pattern or a first heat dissipation pattern. The second separated pattern 334 may be a second dummy pattern or a second heat dissipation pattern. The through connector 336 may be a dummy through connector or as a heat dissipation through connector.

The dummy region DA may not include a portion outside opposite sides (a left side and a right side in FIG. 4) of the circuit region CA in the second direction (the X-axis direction in the drawings) or a portion along the third edge E3 and/or the fourth edge E4.

For example, in an embodiment, the dummy region DA may be disposed between one edge (e.g., the first side) of the circuit region CA and one edge (e.g., the first edge E1) of the film package 30, and may not be disposed between the other edges of the circuit region CA and other edges (e.g., the second to fourth edges E2, E3, and E4) of the film package 30.

The semiconductor chip 360 may be disposed in the chip region MA on the first surface 311 of the base film 310. For example, a terminal of the semiconductor chip 360 may be electrically connected to a portion of the circuit pattern 320 exposed in the chip region MA. For example, as illustrated in FIG. 3, a connection bump 362 may be disposed between the semiconductor chip 360 and the circuit pattern 320, and the semiconductor chip 360 and the circuit pattern 320 may be electrically connected through the connection bump 362. A molding portion 364 may be disposed on an upper portion and/or a side portion of the semiconductor chip 360. The molding portion 364 may protect the semiconductor chip 360 and a portion of the circuit pattern 320 in the chip region MA and stably fix the semiconductor chip 360. The molding portion 364 may include or may be formed of any of various materials (e.g., an epoxy resin, or the like).

In an embodiment, the semiconductor chip 360 may be disposed closer to the first outer terminal 322a or the first terminal region OA1 than the second outer terminal 322b or the second terminal region OA2. For example, in the first direction (the Y-axis direction in the drawings), a second distance D2 between the semiconductor chip 360 and the second outer terminal 322b may be greater than a first distance D1 between the semiconductor chip 360 and the first outer terminal 322a. Additionally, the semiconductor chip 360 may be disposed closer to the first edge E1 of the film package 30 than the second edge E2 of the film package 30. For example, in the first direction (the Y-axis direction in the drawings), a distance between the semiconductor chip 360 and the first edge E1 of the film package 30 may be less than a distance between the semiconductor chip 360 and the second edge E2 of the film package 30.

Thereby, the semiconductor chip 360 may be disposed in the unfolded portion NP, and a damage of the semiconductor chip 360 or the like may be prevented in a folded state of the film package 30. However, the embodiments are not limited thereto, and the semiconductor chip 360 may be disposed at a central portion in the first direction (the Y-axis direction in the drawings). Various other modified embodiments are possible.

The circuit pattern 320 may include a plurality of patterns. The plurality of patterns may be partially disposed on the first surface 311 and/or the second surface 312 of the base film 310 to have a predetermined pattern. In an embodiment, the circuit pattern 320 may include the first circuit pattern 322 including a plurality of patterns. The plurality of patterns of the first circuit pattern 322 may be partially disposed on the first surface 311 and/or the second surface 312 of the base film 310 to have a predetermined pattern.

The circuit pattern 320 may include any of various patterns, wirings, terminals, or the like configured to connect the semiconductor chip 360 that is disposed in the chip region MA and an external device. By the circuit pattern 320, a signal transmission between the semiconductor chip 360 and the external device, a power supply to the semiconductor chip 360, or the like may be achieved.

For example, the first circuit pattern 322 may include the first outer terminal 322a, the second outer terminal 322b, and a wiring 322c. The wiring 322c may be disposed in the chip region MA. The wiring 322c may electrically connect the first outer terminal 322a and the semiconductor chip 360 and/or may electrically connect the second outer terminal 322b and the semiconductor chip 360.

The first outer terminal 322a and the second outer terminal 322b may be disposed at opposite sides in the first direction (the Y-axis direction in the drawings) in the circuit region CA. For example, the first outer terminal 322a may be disposed at a first side (an upper side in FIG. 4) in the first direction that is adjacent to the printed circuit board 20, and the second outer terminal 322b may be disposed at a second side (a lower side in FIG. 4) in the first direction that is opposite to the first side and is adjacent to the display panel 10. The first outer terminal 322a and/or the second outer terminal 322b may include a plurality of individual conductive layers. The plurality of individual conductive layers may have an elongated shape (e.g., extending in the first direction (Y-axis direction)) and may be spaced apart in the second direction (X-axis direction).

The first outer terminal 322a may be a terminal configured to be electrically connected to the printed circuit board 20 (e.g., the pad 20p of the printed circuit board 20), and the second outer terminal 322b may be a terminal configured to be electrically connected to the display panel 10 (e.g., the pad 10p of the display panel 10). The first outer terminal 322a may be an input terminal, and the second outer terminal 322b may be an output terminal.

A line width of the first outer terminal 322a may be greater than a line width of the second outer terminal 322b. A pitch or an interval of the first outer terminal 322a may be greater than a pitch or an interval of the second outer terminal 322b. The first outer terminal 322a may receive control signals from the printed circuit board 20. With respect to the second outer terminal 322b, the first outer terminal 322a may have a relatively large line width, pitch, or interval. The second outer terminal 322b may apply pixel signals to the display panel 10. With respect to the first outer terminal 322a, the second outer terminal 322b may have a relatively small line width, pitch, or interval.

In an embodiment, the separated pattern 330 may include the first separated pattern 332. The first separated pattern 332 may be disposed on the first surface 311 of the base film 310 and may be spaced apart from the first circuit pattern 322 in a plan view. The separated pattern 330 may further include the second separated pattern 334 that is disposed on the second surface 312 of the base film 310. The separated pattern 330 may further include the through connector 336. The through connector 336 may penetrate or pass through the base film 310 and connect (e.g., directly connect) the first separated pattern 332 and the second separated pattern 334.

The separated pattern 330 may be a pattern that is spaced apart from the circuit pattern 320 and is electrically separated (e.g., isolated) or insulated from the circuit pattern 320. For example, the first separated pattern 332 may be spaced apart from, be electrically separated (e.g., isolated) from, or be insulated from the first circuit pattern 322 and/or the second circuit pattern. The second separated pattern 334 may be spaced apart from, be electrically separated (e.g., isolated) from, or be insulated from the first circuit pattern 322 and/or the second circuit pattern. The through connector 336 may be spaced apart from, be electrically separated (e.g., isolated) from, or be insulated from the first circuit pattern 322 and/or the second circuit pattern.

Even if the separated pattern 330 includes a portion connected to a portion of the circuit pattern 320, when the separated pattern 330 does not perform an operation of the circuit pattern 320, the separated pattern 330 may be regarded as a pattern that is electrically separated (e.g., isolated) or insulated from the circuit pattern 320. For example, when signals related to an operation of the semiconductor chip 360, signals transmitted from the printed circuit board 20, signals transmitted to the display panel 10, or the like is not applied to the separated pattern 330, the separated pattern 330 may be regarded as the pattern that is electrically separated (e.g., isolated) or insulated from the circuit pattern 320. The separated pattern 330 may include or may be formed of metal and may be configured to dissipate heat. The separated pattern 330 may be referred to as a heat dissipation pattern, a heat dissipation metal pattern, a heat dissipation conductive pattern, a separated metal pattern, a separated conductive pattern, or the like. For example, the separated pattern 330 may be a heat dissipation pattern configured to form a heat dissipation path to or toward the printed circuit board 20.

The first separated pattern 332 may be disposed outside the first outer terminal 322a in the first direction (the Y-axis direction in the drawings). For example, the first separated pattern 332 may be disposed between the first outer terminal 322a and the first edge E1 of the film package 30 in the first direction. For example, the first separated pattern 332 may be disposed outside the first outer terminal 322a that is connected to the printed circuit board 20 and has a relatively large width, pitch, or interval. Thereby, the first separated pattern 332 may overlap the printed circuit board 20 in a plan view, and the first separated pattern 332 may be disposed between the base film 310 and the printed circuit board 20 in a third direction (a Z-axis direction (vertical direction) in the drawings) of the film package 30.

In an embodiment, the first separated pattern 332 may be disposed outside the first side (the upper side in FIG. 4) of the circuit region CA in the first direction (the Y-axis direction in the drawings), and may have a shape extending in the second direction (the X-axis direction in the drawings). For example, the first separated pattern 332 may have a line shape or a bar shape that has a first width W1 in the first direction and a first length L1 in the second direction. Thereby, the first separated pattern 332 may have a sufficient area in the dummy region DA that is outside the first outer terminal 322a. However, the embodiments are not limited thereto, and a shape of the first separated pattern 332 may be variously modified.

The first width W1 of the first separated pattern 332 may be greater than a thickness of the base film 310. The first width W1 of the first separated pattern 332 may be greater than a thickness of the circuit pattern 320 (e.g., the first circuit pattern 322) or a thickness of the separated pattern 330 (e.g., the first separated pattern 332 or the second separated pattern 334). For example, the first width W1 of the first separated pattern 332 may be 1 mm or more (e.g., 3 mm or more, as an example, 5 mm or more). Thereby, the first width W1 of the first separated pattern 332 may be sufficiently large such that a heat dissipation property may be enhanced. The first width W1 of the first separated pattern 332 may be 30 mm or less (e.g., 20 mm or less). Thereby, a size of the dummy region DA may be prevented forming being beyond a certain level. However, the embodiments are not limited thereto, and the first width W1 of the first separated pattern 332 may be less than 1 mm or greater than 30 mm.

In an embodiment, the first width W1 of the first separated pattern 332 may be greater than a length L2 of the first outer terminal 322a in the first direction (the Y-axis direction in the drawings). Thereby, the first width W1 of the first separated pattern 332 may be sufficient and a heat dissipation property may be enhanced. However, the embodiments are not limited thereto, and the first width W1 of the first separated pattern 332 may be the same as or less than the length L2 of the first outer terminal 322a in the first direction.

In an embodiment, the first width W1 of the first separated pattern 332 may be greater than a length L3 of the second outer terminal 322b in the first direction (the Y-axis direction in the drawings). Thereby, the first width W1 of the first separated pattern 332 may be sufficient and a heat dissipation property may be enhanced. However, the embodiments are not limited thereto, and the first width W1 of the first separated pattern 332 may be the same as or less than the length L3 of the second outer terminal 322b in the first direction.

In an embodiment, the first width W1 of the first separated pattern 332 may be greater than a first distance D1 between the semiconductor chip 360 and the first outer terminal 322a in the first direction (the Y-axis direction in the drawings). Thereby, the first width W1 of the first separated pattern 332 may be sufficient and a heat dissipation property may be enhanced. However, the embodiments are not limited thereto, and the first width W1 of the first separated pattern 332 may be the same as or less than the first distance D1 between the semiconductor chip 360 and the first outer terminal 322a in the first direction.

A ratio (L1/L) of the first length L1 of the first separated pattern 332 to a length L of the film package 30 in the second direction (the X-axis direction in the drawings) may be 50% to 100% (e.g., 80% to 100%, as an example, 90% to 100%). However, the embodiments are not limited thereto, and the ratio (L1/L) of the first length L1 of the first separated pattern 332 to the length L of the film package 30 in the second direction may be less than 50%.

The first separated pattern 332 may not be disposed outside the second side (the lower side in FIG. 4) of the circuit region CA opposite to the first side of the circuit region CA in the first direction. For example, the first separated pattern 332 may be disposed near the first edge E1 of the film package 30 and may not be disposed near the second edge E2 of the film package 30, and may have an asymmetrical shape in the first direction.

The first separated pattern 332 may not include a portion outside opposite sides (the left side and the right side in FIG. 4) of the circuit region CA in the second direction (the X-axis direction in the drawings) or a portion along the third edge E3 and/or the fourth edge E4.

For example, in an embodiment, the first separated pattern 332 may be disposed between one edge (e.g., the first side) of the circuit region CA and one edge (e.g., the first edge E1) of the film package 30, and may not be disposed between other edges of the circuit region CA and other edges (e.g., the second to fourth edges E2, E3, and E4) of the film package 30.

The second separated pattern 334 may be disposed at least in the dummy region DA on the second surface 312 of the base film 310. For example, at least a portion of the second separated pattern 334 may vertically overlap the dummy region DA. More particularly, the second separated pattern 334 may be disposed in the dummy region DA and extend from the dummy region DA such that the second separated pattern 334 is also included in at least a portion of the circuit region CA. For example, the second separated pattern 334 may vertically overlap the dummy region DA, and at least a portion of the circuit region CA in the third direction (the Z-axis direction in the drawings). Accordingly, an area of the second separated pattern 334 that is disposed in the dummy region DA and the circuit region CA may be greater than an area of the first separated pattern 332 that is disposed in the dummy region DA and is not disposed in the circuit region CA.

In an embodiment, in a plan view, the second separated pattern 334 may overlap the semiconductor chip 360 in the third direction. For example, the second separated pattern 334 may vertically overlap the semiconductor chip 360. In the circuit region CA, the second separated pattern 334 may extend from the first side (the upper side in FIG. 5) of the circuit region CA that is adjacent to the dummy region DA to at least an edge of the semiconductor chip 360 that is adjacent to the second side (the lower side in FIG. 5) of the circuit region CA. Accordingly, in a plan view, an entire region of the semiconductor chip 360 may overlap the second separated pattern 334. When the second separated pattern 334 overlaps the semiconductor chip 360 that generates a large amount of heat, the heat generated in the semiconductor chip 360 may be further dissipated through a heat dissipation path including the second separated pattern 334, the through connector 336, the first separated pattern 332, and the printed circuit board 20. For example, heat transferred from the semiconductor chip 360 may be further dissipated through the heat dissipation path when the second separated pattern 334 overlaps a greater area of the base film 310 in the third direction (the Z-axis direction in the drawings). Heat transferred from the semiconductor chip 360 may also be further dissipated through the heat dissipation path when the second separated pattern 334 extends into the circuit region CA such that the second separated pattern 334 overlaps the printed circuit board 20 in the third direction (the Z-axis direction in the drawings).

For example, in a plan view, a ratio of an area of the second separated pattern 334 to an entire area of the film package 30 may be 40% to 100%. The ratio of the area of the second separated pattern 334 to the entire area of the film package 30 may be 40% or more, an area of the second separated pattern 334 may be sufficiently large such that the second separated pattern 334 may stably overlap the semiconductor chip 360.

However, the embodiments are not limited thereto. In some embodiments, the second separated pattern 334 may not be disposed in the circuit region CA, or may not overlap an entire region of the semiconductor chip 360. In some embodiments, the ratio of the area of the second separated pattern 334 to the entire area of the film package 30 may be less than 40%.

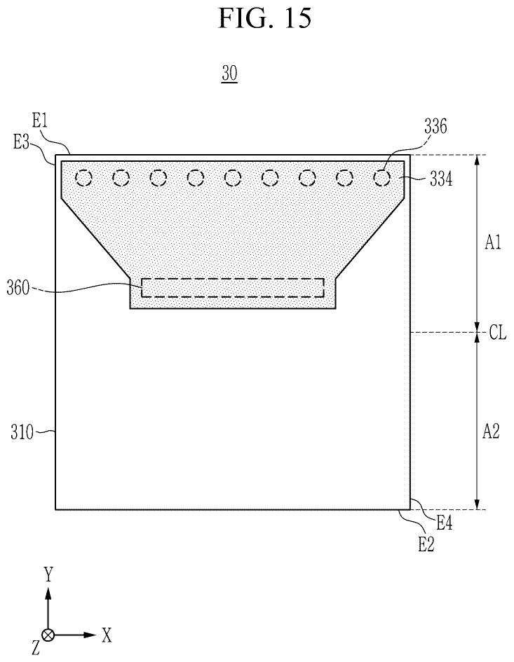

In FIG. 5, it is illustrated as an example that the second separated pattern 334 may have a planar shape of a rectangular shape. However, the embodiments are not limited thereto, and the second separated pattern 334 may have any of various planar shapes. In an embodiment, in the first direction (the Y-axis direction in the drawings), a third distance D3 may be greater than a fourth distance D4. The third distance D3 may be a distance between a first edge of the second separated pattern 334 that is adjacent to the first edge E1 of the film package 30 and the semiconductor chip 360. The fourth distance may be a distance between a second edge of the second separated pattern 334 that is adjacent to the second edge E2 of the film package 30 and the semiconductor chip 360. Thereby, the second separated pattern 334 may have a large area in a portion adjacent to the first edge E1 of the film package 30. Accordingly, a heat dissipation path from the semiconductor chip 360 to the printed circuit board 20, and the separated pattern 330 may be stably formed. Additionally, areas of the second separated pattern 334 and the second protective layer 354 may be reduced in size, and, as a result, a cost reduction may be achieved. However, the embodiments are not limited thereto. Another embodiment will be described later in more detail with reference to FIG. 15.

A heat dissipation path as described herein includes components thermally connected such that heat will follow a path between the components to allow the heat to transfer across the components (e.g., from a first component to a last component in the thermal connection). Simply because two components are part of the same device or package does not mean that a heat dissipation path is formed between these two components. In general, components which are heat-conductive and directly connected to other heat-conductive or heat-generating components (or connected to those components through intermediate heat-conductive components or in such close proximity as to permit a substantial transfer of heat) will be described as forming a heat dissipation path. On the contrary, two components with heat-insulative materials therebetween, which materials significantly prevent heat transfer between the two components, or only allow for incidental heat transfer, are not described as forming or equating to a heat dissipation path. Components included in a heat dissipation path are components formed of materials that are typically known as good heat conductors or known to have utility for transferring heat.

In an embodiment, the second separated pattern 334 may not be directly connected to the semiconductor chip 360. For example, the base film 310 may be disposed between the second separated pattern 334 and the semiconductor chip 360, and the second separated pattern 334 is indirectly connected to the semiconductor chip 360. In this instance, the heat generated in the semiconductor chip 360 may easily reach the second separated pattern 334 through or via the base film 310 having a small thickness and may be dissipated through the second separated pattern 334, the through connector 336, the first separated pattern 332, and the printed circuit board 20. Accordingly, the heat generated in the semiconductor chip 360 may be dissipated through the second separated pattern 334 and a manufacturing process may be simple. However, the embodiments are not limited thereto. In some embodiments, an additional heat dissipation path that directly connects the semiconductor chip 360 (or the connection bump 362 connected to the semiconductor chip 360) to the second separated pattern 334 through the base film 310 may be included to further dissipate heat from the semiconductor chip 360. Various other modified embodiments are possible.

The through connector 336 may penetrate or pass through the base film 310 in the dummy region DA and connect (e.g., directly connect) the first separated pattern 332 and the second separated pattern 334. By a heat dissipation path between the first separated pattern 332 and the second separated pattern 334, the heat dissipation property may be enhanced. However, the embodiments are not limited thereto, and the through connector 336 may be omitted.

In the second direction (the X-axis direction in the drawings), a plurality of through connectors 336 may be disposed at regular intervals. Thereby, the first separated pattern 332 and the second separated pattern 334 may be uniformly connected.

In an embodiment, an interval of the through connector 336 may be greater than a width of the through connector 336. The interval of the through connector 336 may refer to a minimum interval in the second direction, and the width of the through connector 336 may refer to a maximum width (e.g., a diameter). Thereby, the through connector 336 may be stably formed. However, a size, a position, an arrangement, or the like of the through connector 336 may be variously modified.

In the drawings, it is illustrated as an example that the through connector 336 has a planar shape of a circular shape. However, the embodiments are not limited thereto, and the planar shape of the through connector 336 may be variously modified.

The protective layer 350 that is disposed on the circuit pattern 320 and/or the separated pattern 330 may prevent oxidation, damage, delamination, or the like of the circuit pattern 320 and/or the separated pattern 330. The protective layer 350 may further provide electrical insulation with respect to the circuit patterns 320 and the separated pattern 330. The protective layer 350 may include or may be formed of a solder resist. For example, the protective layer 350 may include or may be formed of a thermosetting solder resist, or the like. However, the embodiments are not limited to a material of the protective layer 350.

The protective layer 350 may include the first protective layer 352 that is disposed on the first surface 311 of the base film 310, and the second protective layer 354 that is disposed on the second surface 312 of the base film 310.

In an embodiment, the first protective layer 352 may be disposed on the first circuit pattern 322 in the cover region SA, and may not be disposed in the chip region MA, the first terminal region OA1, the second terminal region OA2, and the dummy region DA. The second protective layer 354 may be disposed on an entire portion of the second separated pattern 334. For example, the second protective layer 354 may be partially disposed to correspond to a portion where the second separated pattern 334 is disposed, and may not be disposed in a portion where the second separated pattern 334 is not disposed. Thereby, cost of a process of forming the second protective layer 354 may be reduced and weight of the film package 30 may be reduced. However, the embodiments are not limited thereto, and the second protective layer 354 may be entirely disposed on the second surface 312 of the base film 310 and the second separated pattern 334.

In an embodiment, the circuit pattern 320 may include or may be formed of a conductive material (e.g., metal). In a manufacturing process, the circuit pattern 320 may include a plurality of conductive material layers (e.g., a plurality of metal layers). This will be described later in more detail in a manufacturing method of a film package 30. Even when the circuit pattern 320 may include the plurality of conductive materials, the plurality of conductive material layers may include the same material and a boundary between the plurality of conductive material layers may not be confirmed in a final structure. In FIG. 3, it is illustrated as an example that the circuit pattern 320 is formed of one layer.

In an embodiment, the circuit pattern 320 (e.g., the first circuit pattern 322) may be formed of a plating layer. For example, the circuit pattern 320 (e.g., the first circuit pattern 322) may include at least one of copper (Cu), aluminum (Al), chromium (Cr), nickel (Ni), silver (Ag), molybdenum (Mo), gold (Au), titanium (Ti), or tantalum (Ta), or may include an alloy including the above material. However, the embodiments are not limited thereto, and a material of the circuit pattern 320 may be variously modified.

For example, the circuit pattern 320 (e.g., the first circuit pattern 322) may have a thickness of 3 μm to 25 μm. However, the embodiments are not limited thereto, and the circuit pattern 320 may have any of various thicknesses.

In an embodiment, the circuit pattern 320 may be in contact with the base film 310, and the base film 310 may be exposed between the plurality of patterns of the circuit pattern 320. For example, the first circuit pattern 322 may be in contact with the first surface 311 of the base film 310, and the first surface 311 of the base film 310 may be exposed between the plurality of patterns of the first circuit pattern 322. However, the embodiments are not limited thereto, and an additional layer (e.g., a buffer layer) may be further disposed between the circuit pattern 320 and the base film 310. For example, a buffer layer may be disposed between the first circuit pattern 322 and the first surface 311 of the base film 310. The buffer layer may be configured to improve adhesion between the base film 310 and the circuit pattern 320 or prevent unnecessary element movement that may occur between the base film 310 and the circuit pattern 320. The buffer layer may include or may be formed of a conductive material (metal, semiconductor, metal nitride, or the like) and may not include a resin. Various other modified embodiments are possible.

In an embodiment, the circuit pattern 320 and the separated pattern 330 that are included in the conductive pattern 340 may be formed together by the same process. For example, the separated pattern 330 (e.g., the first separated pattern 332, the second separated pattern 334, and/or the through connector 336) and the circuit pattern 320 (e.g., the first circuit pattern 322) may be formed together by the same process.

In an embodiment, the first separated pattern 332 and the first circuit pattern 322 may be formed together by the same process. Thereby, the first separated pattern 332 and the first circuit pattern 322 may include the same material, and the first separated pattern 332 and the first circuit pattern 322 may be disposed on the same layer (e.g., the same vertical level in the third direction). The first separated pattern 332 may have the same thickness, cross-sectional structure, or stacking structure as the first circuit pattern 322.

In an embodiment, the first separated pattern 332 may include or may be formed of the same plating layer as the first circuit pattern 322. For example, the first separated pattern 332 and the first circuit pattern 322 may include or may be formed of the same material, such as at least one of copper (Cu), aluminum (Al), chromium (Cr), nickel (Ni), silver (Ag), molybdenum (Mo), gold (Au), titanium (Ti), or tantalum (Ta), or may include or may be formed of an alloy including those materials. However, the embodiments are not limited thereto, and a material of the first separated pattern 332 may be variously modified.

The first separated pattern 332 and the first circuit pattern 322 may have the same thickness. In this specification, the same thickness may include a case where there is a thickness difference within a process error. In some cases, the thickness can vary by a small percentage (e.g., 10%). For example, the first separated pattern 332 may have a thickness of 3 μm to 25 μm. However, the embodiments are not limited thereto, and the first separated pattern 332 may have any of various thicknesses.

In an embodiment, the first separated pattern 332 may be in contact with the first surface 311 of the base film 310. When an additional layer (e.g., the buffer layer) is disposed between the first circuit pattern 322 and the first surface 311 of the base film 310, the additional layer (e.g., the buffer layer) may also be disposed between the first separated pattern 332 and the first surface 311 of the base film 310. For example, the first separated pattern 332 and the first circuit pattern 322 may have the same cross-sectional structure or stacking structure.

In an embodiment, the first separated pattern 332 and the second separated pattern 334 may have the same thickness. By forming the first separated pattern 332 and the second separated pattern 334, which are disposed on the first surface 311 and the second surface 312 of the base film 310, respectively, by the same process, a process may be simplified. This will be described later in more detail in a manufacturing method of a film package 30.

In an embodiment, the second separated pattern 334 may include the same material as the first circuit pattern 322 or the first separated pattern 332. The second separated pattern 334 may have the same thickness, cross-sectional structure, or stacking structure as the first circuit pattern 322 or the first separated pattern 332.

In an embodiment, the second separated pattern 334 may include or may be formed of the same plating layer as the first circuit pattern 322 or the first separated pattern 332. For example, the second separated pattern 334 may include or may be formed of the same material as a material of the first circuit pattern 322 or the first separated pattern 332. For example, the second separated pattern 334 may include or may be formed of at least one of copper (Cu), aluminum (Al), chromium (Cr), nickel (Ni), silver (Ag), molybdenum (Mo), gold (Au), titanium (Ti), or tantalum (Ta), or may include or may be formed of an alloy including those materials. However, the embodiments are not limited thereto, and a material of the second separated pattern 334 may be variously modified.

The second separated pattern 334 may have the same thickness as the first circuit pattern 322 or the second separated pattern 334. For example, the second separated pattern 334 may have a thickness of 3 μm to 25 μm. However, the embodiments are not limited thereto, and the second separated pattern 334 may have any of various thicknesses.

In an embodiment, the second separated pattern 334 may be in contact with the second surface 312 of the base film 310. When an additional layer (e.g., a buffer layer) is disposed between the first circuit pattern 322 and the first surface 311 of the base film 310 or between the second circuit pattern 332 and the first surface 311 of the base film 310, an additional layer (e.g., a buffer layer) may be disposed between the second separated pattern 334 and the second surface 312 of the base film 310. For example, the second separated pattern 334 may have a cross-sectional structure or stacking structure corresponding to a cross-sectional structure or stacking structure of the first circuit pattern 322 or the first separated pattern 332.

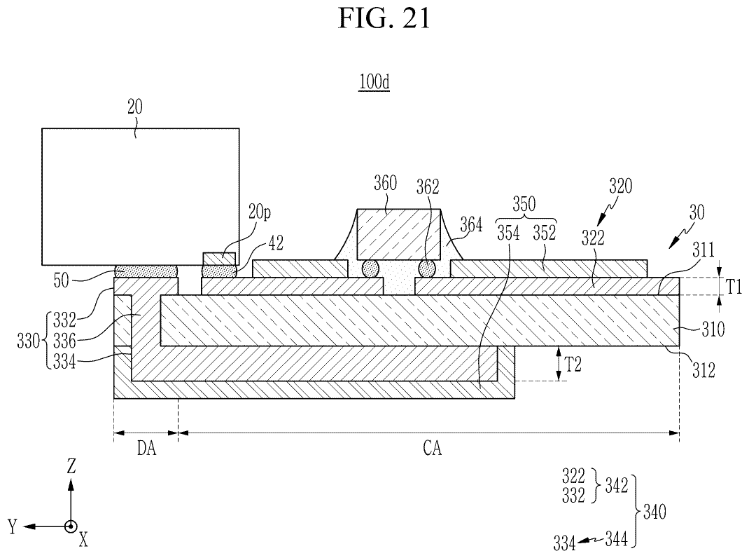

However, the embodiments are not limited thereto. In some embodiments, at least a portion of a process of forming the second separated pattern 334 may be separately performed from a process of forming the first circuit pattern 322 or the first separated pattern 332. Accordingly, the second separated pattern 334 may include a material different from a material of the first circuit pattern 322 or the second separated pattern 334, or may have a thickness, cross-sectional structure, or stacking structure different from a thickness, cross-sectional structure, or stacking structure of the first circuit pattern 322 or the second separated pattern 334. An embodiment in which at least a portion of a process of forming the second separated pattern 334 may be separately formed from a process of forming the first circuit pattern 322 or the first separated pattern 332 will be described later in detail with reference to FIG. 21.

The through connector 336 that connects the first separated pattern 332 and the second separated pattern 334 may include the same material as a material of the first separated pattern 332 and/or the second separated pattern 334. For example, the through connector 336 may include or may be formed of at least one of copper (Cu), aluminum (Al), chromium (Cr), nickel (Ni), silver (Ag), molybdenum (Mo), gold (Au), titanium (Ti), or tantalum (Ta), or may include or may be formed of an alloy including those materials. The through connector 336 may be formed by a process of forming the first separated pattern 332 and/or the second separated pattern 334. However, the embodiments are not limited thereto. The through connector 336 may be formed by a process different from the process of forming the first separated pattern 332 and/or the second separated pattern 334.

The first separated pattern 332 may be disposed outside the first outer terminal 322a or the first terminal region OA1 that is connected to the printed circuit board 20, and the first separated pattern 332 may overlap the printed circuit board 20 in a plan view. In the thickness direction (the Z-axis direction in the drawings) of the film package 30, the first separated pattern 332 may be disposed between the first surface 311 of the base film 310 and the printed circuit board 20.

In an embodiment, the first separated pattern 332 may be in contact with the printed circuit board 20, or may be connected to the printed circuit board 20 via an adhesive layer 50 disposed between the first separated pattern 332 and the printed circuit board 20. In FIG. 3, it is illustrated as an example that the adhesive layer 50 is disposed between the first separated pattern 332 and the printed circuit board 20. The adhesive layer 50 may include the same material as a material of the first conductive adhesive layer 42 that electrically connects the pad 20p of the printed circuit board 20 and the first outer terminal 322a. For example, the adhesive layer 50 may be an anisotropic conductive film (ACF).. Alternatively, the adhesive layer 50 may include a material different from the first conductive adhesive layer 42. For example, the adhesive layer 50 may have low electrical conductivity (i.e., an insulator) and high thermal conductivity. For example, the adhesive layer 50 may include a thermally conductive adhesive. However, the embodiments are not limited thereto, and the adhesive layer 50 may be omitted and the first separated pattern 332 may be in contact with the printed circuit board 20. Since a thickness of the first conductive adhesive layer 42 is small, the first separated pattern 332 may be stably in contact with the printed circuit board 20 without the adhesive layer 50.

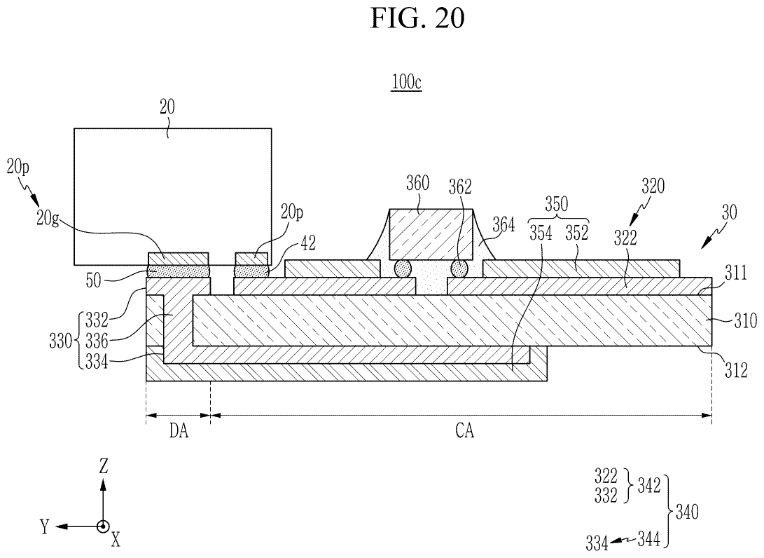

For example, the first separated pattern 332 may be connected to a protective layer (e.g., a solder resist layer) of the printed circuit board 20. Thereby, the first separated pattern 332 may be connected to an insulation portion of the printed circuit board 20 and an electrical insulating property may be enhanced. However, the embodiments are not limited thereto. An embodiment will be described later in more detail with reference to FIG. 20.

In an embodiment, the first separated pattern 332 may be disposed outside the first outer terminal 322a or the first terminal region OA1 in the first direction (the Y-axis direction in the drawings) and may be connected to the printed circuit board 20 directly or through the adhesive layer 50. Thereby, the film package 30 may have a heat dissipation path to the printed circuit board 20. The printed circuit board 20 may have a thickness greater than a thickness of the film package 30 and may include a wiring layer including or being formed of metal with enhanced thermal conductivity, and may act as a kind of a heat sink. The first separated pattern 332 may include or may be formed of a material including a conductive material and a size of the heat path may be reduced. Thereby, the heat dissipation property of the film package 30 may be enhanced.

The separated pattern 330 may include the first separated pattern 332 and the second separated pattern 334 that are disposed on opposite surfaces of the film package 30, and the separated pattern 330 may have a large area. Accordingly, the heat dissipation property may be further enhanced. Additionally, by including the through connector 336 that connects the first separated pattern 332 and the second separated pattern 334, the heat dissipation property may be further enhanced.

By enhancing the heat dissipation property of the film package 30, the heat generated in the semiconductor chip 360 when the semiconductor chip 360 operates may be effectively dissipated, and performance of the semiconductor chip 360 and the film package 30 including the same may be enhanced..

In an embodiment, the separated pattern 330 may be formed in a process of forming the circuit pattern 320. Accordingly, a manufacturing process of the film package 30 may be simplified and a shape or arrangement freedom of the separated pattern 330 may be enhanced. The separated pattern 330 may have the same thickness as a thickness of the circuit pattern 320, and a thickness and weight of the film package 30 may be reduced.

On the other hand, in a comparative example in which a metal tape that is separately manufactured from a circuit pattern of a film package is used, the metal tape may have a thickness, cross-sectional structure, or stacking structure different from a thickness, cross-sectional structure, or stacking structure of the circuit pattern. Further, the metal tape may not be disposed between a base film and a printed circuit board. For example, the metal tape may include an adhesive layer that includes a resin, a metal layer, another adhesive layer that includes a resin, and an insulation layer that includes a resin. Accordingly, the metal tape may have a relatively large thickness. Thereby, this may increase a heat transfer path, increase a thickness and weight of the film package, and cause problems such as delamination of the metal tape or undesirable shape changes of the film package. In addition, a separate mold, attachment apparatus, or the like may be required according to a size, a shape, or the like of the metal tape. Accordingly, when a design of the metal tape is changed, a mold, an attachment apparatus, or the like for forming the metal tape may be changed. As a result, cost for a design change of the metal tape may largely increase, and a variety of a shape in which the metal tape is formed may be low. Further, considering a process of cutting the film package or the like, an arrangement freedom of the metal tape may be low. For example, the metal tape may be attached so that the metal tape is adjacent to the display panel side considering the process of cutting the film package, and it may be difficult to effectively dissipate heat generated in a semiconductor chip adjacent to a printed circuit board.

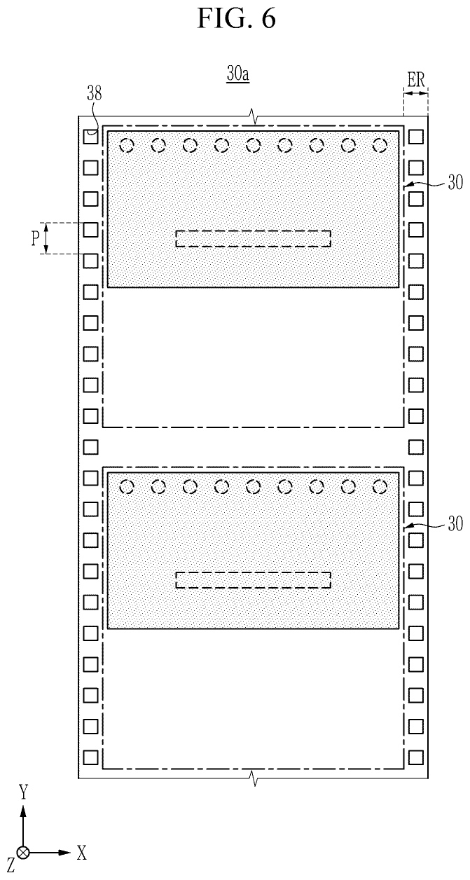

In FIG. 1 to FIG. 5, it is illustrated as an example that the film package 30 has an individually cut shape. Referring to FIG. 6, a film package 30a of a reel shape that includes a plurality of film packages 30 will be described.

FIG. 6 is a rear plan view of a film package 30a of a reel shape that includes a plurality of film packages 30 according to embodiment.

A film package 30a of a reel shape that includes a plurality of film packages 30 may be formed as illustrated in FIG. 6, and a process of cutting the film package 30a of the reel shape into an individual film package 30 may be performed.

In the film package 30a of the reel shape that includes the plurality of film packages 30, edge regions ER may be disposed outside opposite sides (i.e., a third edge and a fourth edge) in a second direction (an X-axis direction in the drawings). In the edge region ER, a plurality of holes 38 may be formed. The plurality of holes 38 may be spaced apart from each other at regular intervals in a first direction (a Y-axis direction in the drawings). By using the plurality of holes 38, the film package 30a of the reel shape may be wound onto a winding reel, or the film package 30a of the reel shape may be unwound from the winding reel. In the process of cutting the film package 30a of the reel shape into the individual film package 30, the edge region ER of the film package 30 may be removed.

For example, a first width W1 (refer to FIG. 4) of a first separated pattern 322 (refer to FIG. 4) may be greater than a pitch P of the plurality of holes 38. Thereby, the first width W1 of the first separated pattern 332 may be sufficient and a heat dissipation property may be enhanced. However, the embodiments are not limited thereto, and the first width W1 of the first separated pattern 332 may be the same as or less than the pitch P of the plurality of holes 38.

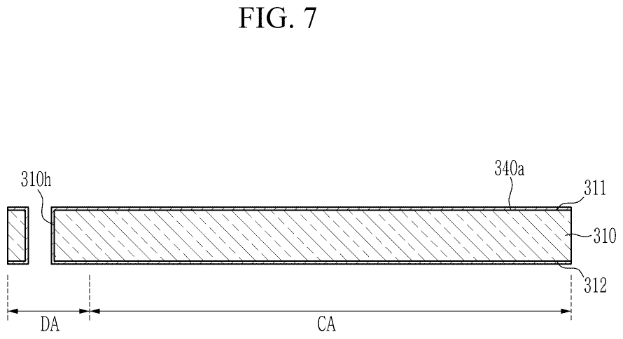

Hereinafter, referring to FIG. 7 to FIG. 14, a manufacturing method of a film package according to an embodiment will be described in detail. To the extent that an element is not described in detail below, it may be understood that the element is at least substantially similar to a corresponding element that has been described elsewhere within the present disclosure.

FIG. 7 to FIG. 14 are cross-sectional views that illustrate a manufacturing method of a film package 30 according to an embodiment.

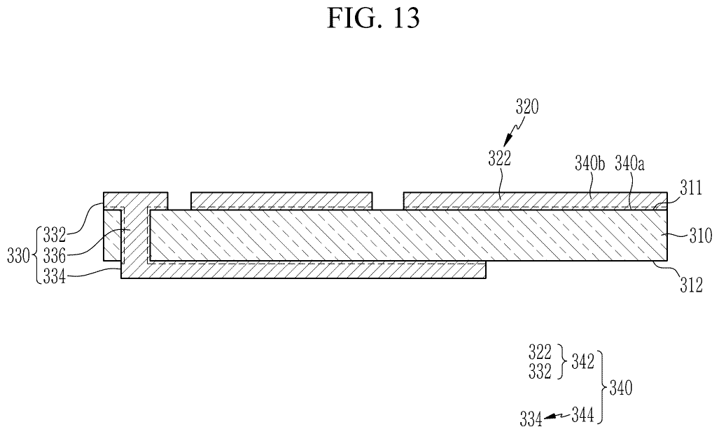

As illustrated in FIG. 7, a through hole 310h may be formed in a base film 310, and at least a portion (e.g., a seed layer 340a) of a conductive pattern 340 (refer to FIG. 13) may be formed on the base film 310.

More particularly, a plurality of through holes 310h may be formed at a region (e.g., a dummy region DA) of the base film 310 in which a first separated pattern 332 (refer to FIG. 13) and a second separated pattern 344 (refer to FIG. 13) overlap each other. For example, the through hole 310h may be formed by a laser drill process. Using the laser drilling process, accuracy may be improved and process time may be reduced. However, the embodiments are not limited thereto, and the through hole 310h may be formed at the base film 310 by any of various processes.

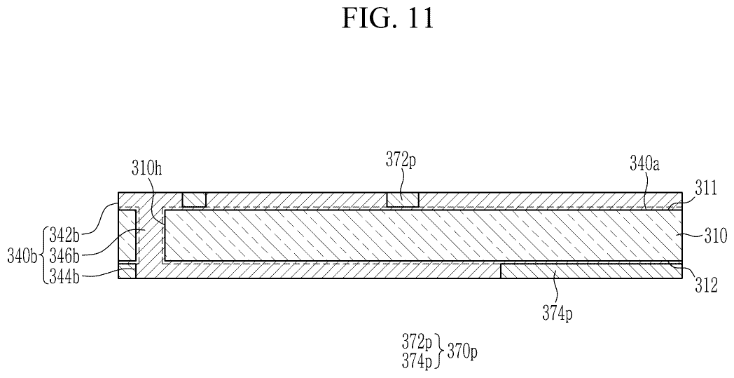

Subsequently, the seed layer 340a may be formed on the base film 310 having the through hole 310h. The seed layer 340a may be a portion of the conductive pattern 340. The seed layer 340a may be formed on a first surface 311 and a second surface 312 of the base film 310, and an inner side surface of the through hole 310h. For example, the seed layer 340a may be a electroless plating layer formed by electroless plating. The seed layer 340a may have a relatively small thickness. For example, the seed layer 340a may have a thickness less than a thickness of a first metal layer 342b (refer to FIG. 11) and/or a thickness of a second metal layer 344b (refer to FIG. 11). For example, a thickness of the seed layer 340a may be 0.1 μm to 2 μm. However, the embodiments are not limited thereto, and the seed layer 340a may have any of various thicknesses.

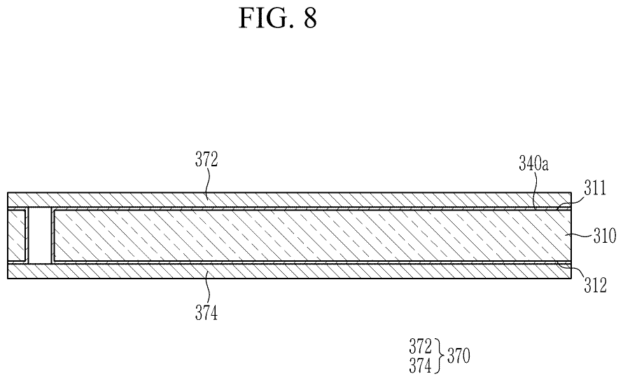

Subsequently, as illustrated in FIG. 8, a photoresist (PR) layer 370 may be formed on the base film 310. More particularly, a first photoresist layer 372 may be formed on the first surface 311 of the base film 310, and a second photoresist layer 374 may be formed on the second surface 312 of the base film 310.

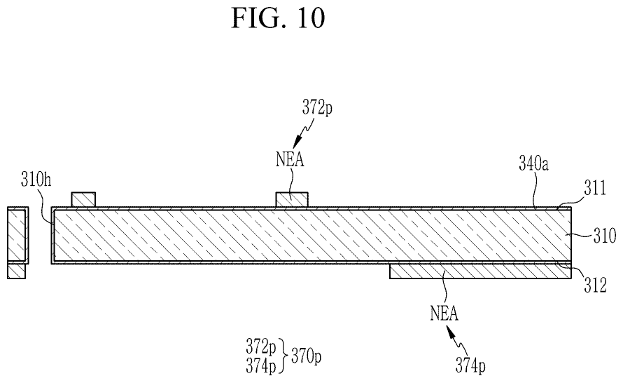

For example, the first photoresist layer 372 and the second photoresist layer 374 may be a dry film that includes or is formed of a photoresist material. When the first photoresist layer 372 and the second photoresist layer 374 is a dry film, the first photoresist layer 372 and the second photoresist layer 374 may be easily formed on the base film 310 by compression, and time and cost of a manufacturing process may be reduced. Further, when the first photoresist layer 372 and the second photoresist layer 374 is a dry film, a defect may be reduced and a photoresist pattern 370 (refer to FIG. 10) with high resolution and precision may be formed. However, the embodiments are not limited thereto, and the first photoresist layer 372 or the second photoresist layer 374 may include other materials.

In an embodiment, the first photoresist layer 372 and the second photoresist layer 374 may be formed at the same time on the first surface 311 and the second surface 312 of the base film 310, respectively. Thereby, a manufacturing process may be simplified. However, the embodiments are not limited thereto, and the first photoresist layer 372 and the second photoresist layer 374 may be formed by different processes.

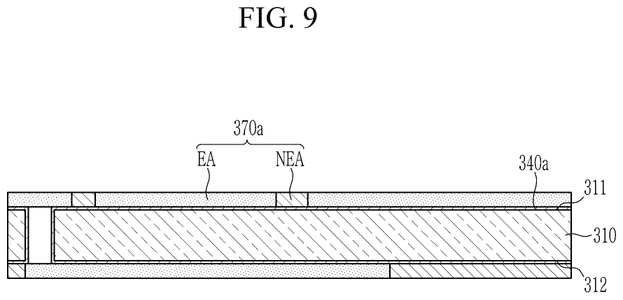

Subsequently, as illustrated in FIG. 9 and FIG. 10, a photoresist pattern 370p may be formed by patterning the photoresist layer 370 (refer to FIG. 8).

More particularly, as illustrated in FIG. 9, by performing an exposure process, the photoresist layer 370a that includes an exposed region EA and an unexposed region NEA may be formed. For example, light supplied from a light source may be provided to a portion of the photoresist layer 370 by using a mask. An area where the light is provided through an opening of the mask may constitute the exposed region EA, and an area where the light is blocked by the mask may constitute the unexposed region NEA.

In some embodiments, a portion removed in a developing process may have a shape corresponding to the conductive pattern 340 including a circuit pattern 320 (refer to FIG. 13) and a separated pattern 330 (refer to FIG. 13). For example, when the exposed region EA is removed in the developing process, the exposed region EA may have a shape corresponding to the conductive pattern 340. For example, when the unexposed region NEA is removed in the developing process, the unexposed region NEA may have a shape corresponding to the conductive pattern 340. In FIG. 9, it is illustrated as an example that the exposed region EA is removed.

Subsequently, as illustrated in FIG. 10, by performing a developing process, the exposure region EA (refer to FIG. 9) may be selectively removed. In some embodiments, as illustrated in FIG. 10, in the developing process, the exposed region EA may be removed, and a photoresist pattern 370p may be formed of the unexposed region NEA. In some embodiments, although not illustrated, the unexposed region NEA may be removed, and the photoresist pattern 370p may be formed of the exposed region EA. After that, a hard bake process may be performed to remove a solvent of the photoresist pattern 370p.

In an embodiment, the photoresist pattern 370p may be disposed in a portion other than the conductive pattern 340 that includes the circuit pattern 320 and the separated pattern 330. For example, in a circuit region, a first photoresist pattern 372p that is disposed on the first surface 311 of the base film 310 may be disposed in a portion other than portions where a first outer terminal 322a, a second outer terminal 322b, and a wiring 322c will be disposed. In a dummy region, the first photoresist pattern 372p that is disposed on the first surface 311 of the base film 310 may be disposed in a portion other than a portion where a first separated pattern 332 will be disposed. For example, a second photoresist pattern 374p that is disposed on the second surface 312 of the base film 310 may be disposed in a portion other than a portion where a second separated pattern 334 will be disposed. The through hole 310h in the dummy region may be exposed to an outside.

In an embodiment, by the developing process, the first photoresist pattern 372p and the second photoresist pattern 374p may be formed at the same time. Thereby, a manufacturing process may be simplified. However, the embodiments are not limited thereto, and other various modified embodiments are possible.

Subsequently, as illustrated in FIG. 11, another portion (e.g., a metal layer 340b) of the conductive pattern 340 may be formed on the base film 310 in a portion other than the photoresist pattern 370p.

The metal layer 340b may include a first metal layer 342b, a second metal layer 344b, and a through metal layer 346b. The first metal layer 342b may be disposed on the first surface 311 of the base film 310. The second metal layer 344b may be disposed on the second surface 312 of the base film 310. The through metal layer 346b may be formed by providing at least a portion of the first metal layer 342b and/or the second metal layer 344b in the through hole 310h.

The metal layer 340b may be another portion of a first conductive pattern 342 and/or a second conductive pattern 344. For example, the metal layer 340b may be an electrolytic plating layer formed by electrolytic plating. The first metal layer 342b and the second metal layer 344b may have a relatively large thickness. For example, the first metal layer 342b and the second metal layer 344b may have a thickness greater than a thickness of the seed layer 340a. A thickness of each of the first metal layer 342b and the second metal layer 344b may be 3 μm to 25 μm. However, the embodiments are not limited thereto, and the first metal layer 342b and the second metal layer 344b may have any of various thicknesses. For example, the thickness of the first metal layer 342b may be different from the thickness of the second metal layer 344b.

The metal layer 340b may be disposed in a portion where the conductive pattern 340 including the circuit pattern 320 and/or the separated pattern 330 will be disposed. For example, the first metal layer 342b that is disposed on the first surface 311 of the base film 310 may correspond to the first outer terminal 322a, the second outer terminal 322b, and the wiring 322c in the circuit region, and may correspond to the first separated pattern 332 in a dummy region. For example, the second metal layer 344b that is disposed on the second surface 312 of the base film 310 may correspond to the second separated pattern 334. The metal layer 340b (e.g., the first metal layer 342b and/or the second metal layer 344b) may fill the through hole 310h in the dummy region.

In an embodiment, the first metal layer 342b that is disposed on the first surface 311 of the base film 310 and the second metal layer 344b that is disposed on the second surface 312 of the base film 310 may be formed at the same time by the same electrolytic plating. Thereby, a manufacturing process may be simplified. However, the embodiments are not limited thereto, and other various modified embodiments are possible.

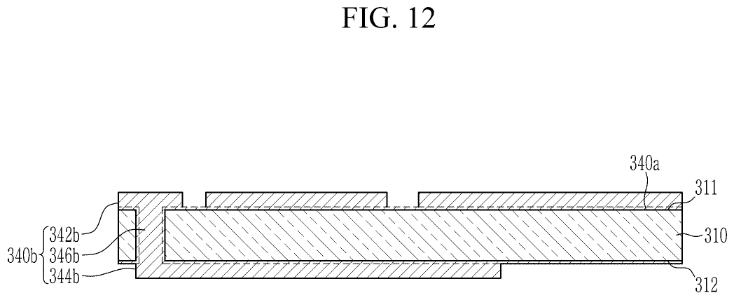

Subsequently, as illustrated in FIG. 12, by performing a strip process, the photoresist pattern 370p (refer to FIG. 11) may be removed. The strip process may be performed by a wet process.

In an embodiment, the first photoresist pattern 372p (refer to FIG. 11) that is disposed on the first surface 311 of the base film 310 and the second photoresist pattern 374p (refer to FIG. 11) that is disposed on the second surface 312 of the base film 310 may be removed at the same time by the same strip process. Thereby, a manufacturing process may be simplified. However, the embodiments are not limited thereto, and other various modified embodiments are possible.

Subsequently, as illustrated in FIG. 13, by performing a flash etching process, a conductive pattern 340 including the seed layer 340a and the metal layer 340b may be formed. In the flash etching process, a portion of the seed layer 340a in which the metal layer 340b is not disposed may be removed. The flash etching process may be performed by a wet process. However, the embodiments are not limited thereto, and the process of removing the portion of the seed layer 340a may be performed by any of various processes.

In an embodiment, a portion of the seed layer 340a that is disposed on the first surface 311 of the base film 310 and a portion of the seed layer 340a that is disposed on the second surface 312 of the base film 310 may be removed at the same time by the same flash etching process. Thereby, a manufacturing process may be simplified. However, the embodiments are not limited thereto, and other various modified embodiments are possible.

In an embodiment, the conductive pattern 340 may include the circuit pattern 320 and the separated pattern 330. For example, in an embodiment, a first conductive pattern 342 that includes a first circuit pattern 322 and a first separated pattern 332 and a second conductive pattern 344 that includes a second separated pattern 334, and a through connector 336 may be formed together. However, the embodiments are not limited thereto.

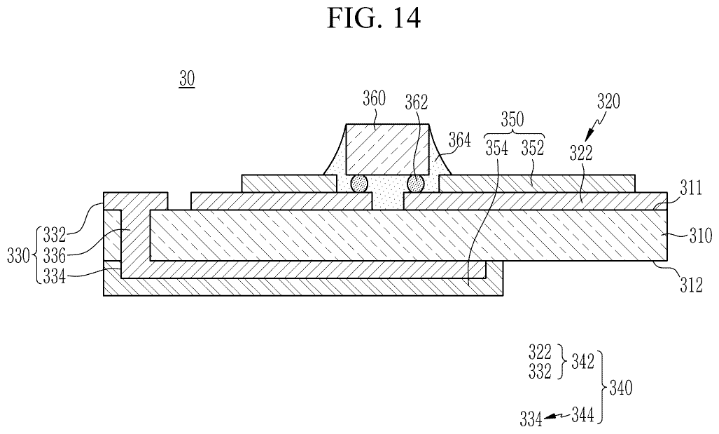

Subsequently, as illustrated in FIG. 14, a protective layer 350 may be formed, a semiconductor chip 360 may be mounted, and a molding portion 364 may be formed.

More particularly, a first protective layer 352 may be formed on the first surface 311 of the base film 310 in a cover region, and a second protective layer 354 may be formed on the second separated pattern 334 on the second surface 312 of the base film 310.

The protective layer 350 having a predetermined shape may be formed by a printing process. However, the embodiments are not limited thereto, and the protective layer 350 may be formed by any of various processes. For example, the protective layer 350 may be entirely formed on the base film 310 and the conductive pattern 340 and a portion of the protective layer 350 may be removed to have a predetermined shape.

Subsequently, by a connection bump 362, a semiconductor chip 360 may be electrically and/or physically connected to a portion of the circuit pattern 320 exposed in a chip region. The molding portion 364 may be formed on a lower portion and/or a side surface of the semiconductor chip 360.

A film package of a reel shape illustrated in FIG. 6 may be formed by the processes described with reference to FIG. 7 to FIG. 14. After that, a process of cutting the film package of the reel shape may be performed. In the process of cutting the film package, a plurality of film package included in the film package of the reel shape may be cut into an individual film package 30 and an edge region of a film package 30 may be removed. Thereby, a film package 30 illustrate in FIG. 3 to FIG. 5 may be formed.

In an embodiment, the separated pattern 330 may be formed in a process of forming the circuit pattern 320, and a manufacturing process of the film package 30 including the separated pattern 330 may be simplified and a shape or arrangement freedom of the separated pattern 330 may be enhanced. The separated pattern 330 may have a thickness the same as a thickness of the circuit pattern 320, and a thickness and weight of the film package 30 may be reduced.

Hereinafter, referring to FIG. 15 to FIG. 21, film packages or semiconductor modules according to embodiments will be described in more detail. To the extent that an element is not described in detail below, it may be understood that the element is at least substantially similar to a corresponding element that has been described elsewhere within the present disclosure.

FIG. 15 is a rear plan view that illustrates a film package 30 according to an embodiment. FIG. 15 illustrates a portion corresponding to FIG. 5. For a clear understanding and simple illustration, in FIG. 15, a second protective layer that is disposed at a rear surface of the film package 30 is omitted.

Referring to FIG. 15, in a film package 30 according to an embodiment, a second separated pattern 334 may be disposed in a first region A1, and may not be disposed in a second region A2. The first region A1 may refer to a region between a first edge E1 of the film package 30 and an imaginary center line CL in a first direction (a Y-axis direction in the drawings) and include a dummy region where a first separated pattern is disposed. The second region A2 may refer to a region between a second edge E2 of the film package 30 and the imaginary center line CL in the first direction. A semiconductor chip 360 may be disposed in the first region A1, and the second separated pattern 334 may extend from the semiconductor chip 360 to the first edge E1 of the film package 30 in the first region A1. In a plan view, the second separated pattern 334 may overlap an entire region of the semiconductor chip 360 and effectively dissipate heat generated in the semiconductor chip 360.

Opposite edges of the second separated pattern 334 in the second direction (the X-axis direction in the drawings) may be inclined to a first direction (a Y-axis direction in the drawings) and the second direction so that a width in the second direction of the second separated pattern 334 increases from a region that is adjacent to the semiconductor chip 360 toward the first edge E1 of the film package 30. Thereby, the heat generated in the semiconductor chip 360 may be effectively dissipated to a printed circuit board.

In an embodiment, by the second separated pattern 334, the heat generated in the semiconductor chip 360 may be effectively dissipated and an area of the second separated pattern 334 may be reduced.

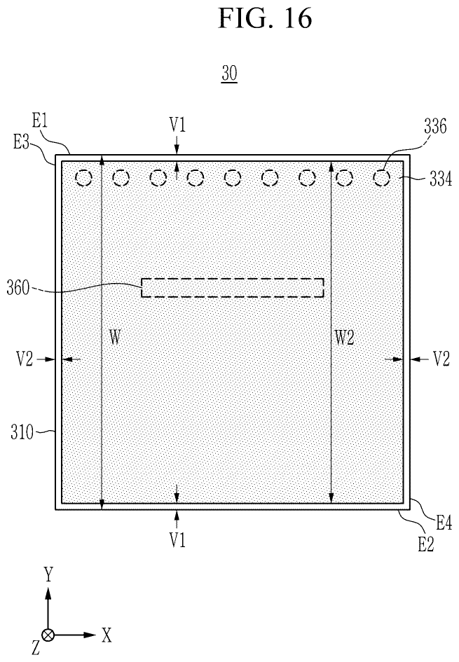

FIG. 16 is a rear plan view that illustrates a film package 30 according to an embodiment. FIG. 16 illustrates a portion corresponding to FIG. 5. For a clear understanding and simple illustration, in FIG. 16, a second protective layer that is disposed at a rear surface of the film package 30 is omitted.

Referring to FIG. 16, in a film package 30 according to an embodiment, a second separated pattern 334 may have a symmetrical shape. For example, in a first direction (a Y-axis direction in the drawings), an interval between a first edge E1 of the film package 30 and a first edge of the second separated pattern 334 adjacent thereto may be a first interval V1, and an interval between a second edge E2 of the film package 30 and a second edge of the second separated pattern 334 adjacent thereto may be the first interval V1. For example, in a second direction (a X-axis direction in the drawings), an interval between a third edge E3 of the film package 30 and a third edge of the second separated pattern 334 may be a second interval V2, and an interval between a fourth edge E4 of the film package 30 and a fourth edge of the second separated pattern 334 may be the second interval V2. For example, the first interval V1 and the second interval V2 may be the same.

For example, a ratio (W2/W) of a second width W2 of the second separated pattern 334 to a width W of the film package 30 in the first direction (the Y-axis direction in the drawings) may be 80% to 100% (e.g., 90% to 100%). However, the embodiments are not limited thereto, and the ratio (W2/W) of the second width W2 of the second separated pattern 334 to the width W of the film package 30 in the first direction may be less than 80%.

For example, a ratio of a second length of the second separated pattern 334 to a length of the film package 30 in the second direction (the X-axis direction in the drawings) may be 80% to 100% (for example, 90% to 100%). However, the embodiments are not limited thereto, and the ratio of the second length of the second separated pattern 334 to the length of the film package 30 in the second direction may be less than 80%.

According to an embodiment, an area of the second separated pattern 334 may be sufficient and the heat dissipation property may be maximized.

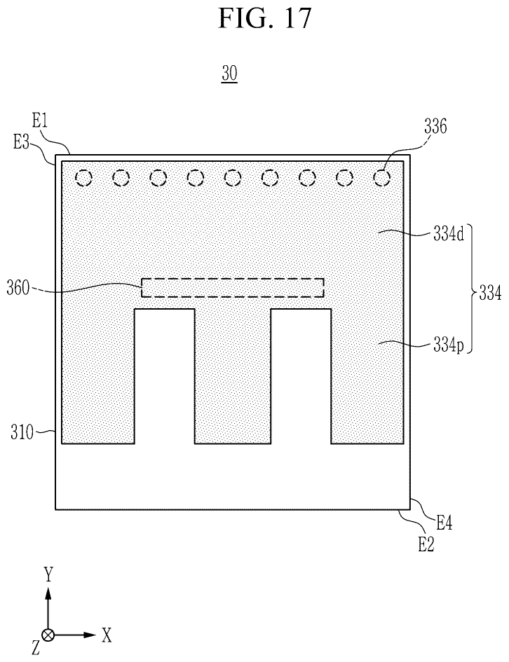

FIG. 17 is a rear plan view that illustrates a film package 30 according to an embodiment. FIG. 17 illustrates a portion corresponding to FIG. 5. For a clear understanding and simple illustration, in FIG. 17, a second protective layer that is disposed at a rear surface of the film package 30 is omitted.

Referring to FIG. 17, in a film package 30 according to an embodiment, a second separated pattern 334 may include a protruding portion 334p. The protruding portion 334p may protrude toward a second edge E2 of the film package 30 in a first direction (a Y-axis direction in the drawings). For example, the second separated pattern 334 may include a main body 334d and a plurality of protruding portions 334p. The main body 334d may overlap a semiconductor chip 360. The plurality of protruding portions 334p may be spaced apart from each other at regular intervals in a second direction (a X-axis direction in the drawings).

According to an embodiment, by the protruding portion 334p of the second separated pattern 334, a heat dissipation path to a display panel may be secured. Thereby, without significantly increasing an area of the second separated pattern 334, the heat dissipation property may be enhanced.

In FIG. 17, it is illustrated as an example that a width of each protruding portion 334p in the second direction (the X-axis direction in the drawings) is greater than an interval between the plurality of protruding portions 334p in the second direction. Thereby, an area of the second separated pattern 334 may increase and the heat dissipation property may be enhanced. However, the embodiments are not limited thereto, and the width of each protruding portion 334p in the second direction may be the same or less than the interval between the plurality of protruding portions 334p in the second direction. In FIG. 17, it is illustrated as an example that an entire length of the plurality of protruding portions 334p (a sum of widths of the plurality of protruding portions 334p) in the second direction (the X-axis direction in the drawings) is greater than an entire interval between the plurality of protruding portions 334p (a sum of intervals between the plurality of protruding portions 334p) in the second direction. Thereby, an area of the second separated pattern 334 may increase and the heat dissipation property may be enhanced. However, the embodiments are not limited thereto, and the entire length of the plurality of protruding portions 334p in the second direction may be the same as or less than the entire interval between the plurality of protruding portions 334p in the second direction.

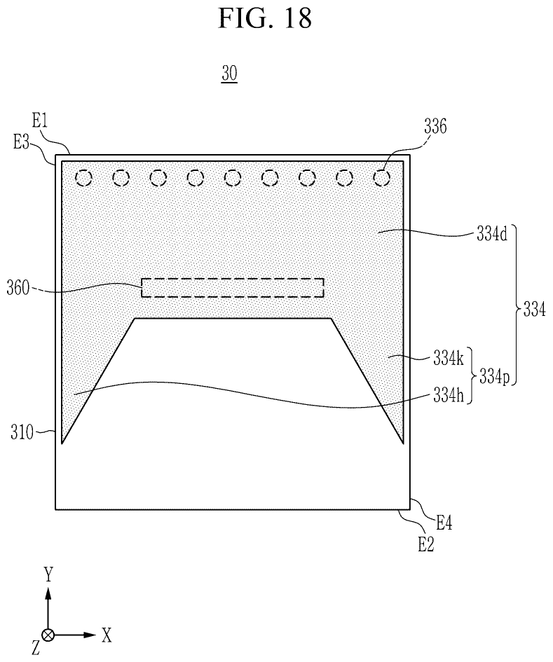

FIG. 18 is a rear plan view that illustrates a film package 30 according to an embodiment. FIG. 18 illustrates a portion corresponding to FIG. 5. For a clear understanding and simple illustration, in FIG. 18, a second protective layer that is disposed at a rear surface of the film package 30 is omitted.

Referring to FIG. 18, in a film package 30 according to an embodiment, a second separated pattern 334 may include a protruding portion 334p. The protruding portion 334p may protrude toward a second edge E2 of the film package 30 in a first direction (a Y-axis direction in the drawings). For example, the second separated pattern 334 may include a main body 334d, and first and second protruding portions 334h and 334k. The main body 334d may overlap a semiconductor chip 360. The first and second protruding portions 334h and 334k may be spaced apart from a third edge E3 and a fourth edge E4 of the film package 30 in a second direction (an X-axis direction in the drawings), respectively.

An outer edge of the first protruding portion 334h in the second direction (the X-axis direction in the drawings) may be parallel to the third edge E3 of the film package 30, and an inner edge of the first protruding portion 334h in the second direction may be inclined so that a width of the first protruding portion 334h in the second direction decreases from a portion that is adjacent to the semiconductor chip 360 to a second edge E2 of the film package 30.

An outer edge of the second protruding portion 334k in the second direction (the X-axis direction in the drawings) may be parallel to the fourth edge E4 of the film package 30, and an inner edge of the second protruding portion 334k in the second direction may be inclined so that a width of the second protruding portion 334k in the second direction decreases from a portion that is adjacent to the semiconductor chip 360 to the second edge E2 of the film package 30.

In an embodiment, by the first protruding portion 334h and the second protruding portion 334k of the second separated pattern 334, heat may be effectively dissipated through opposite edges of the film package 30. Thereby, the heat generated in the semiconductor chip 360 may be effectively dissipated and an area of the second separated pattern 334 may be reduced.

FIG. 19 is a cross-sectional view that illustrates a semiconductor module 100b according to an embodiment. The description of features the same as or substantially similar to features previously discussed above with respect to the semiconductor module 100a illustrated in, for example, FIG. 3, are omitted below for brevity.

Referring to FIG. 19, in an embodiment, a circuit pattern 320 may include a first circuit pattern 322 that is disposed on a first surface 311 of a base film 310 and a second circuit pattern 324 that is disposed on a second surface 312 of the base film 310. For example, the second circuit pattern 324 may be disposed in a portion of a circuit region CA where a second separated pattern 334 is not disposed. The first circuit pattern 322 and the second circuit pattern 324 may be electrically connected to each other by a circuit through connector 326 that penetrates or passes through the base film 310.

A separated pattern 330 (e.g., a first separated pattern 332, a second separated pattern 334, and/or a through connector 336) may be formed by the same process as a process of forming the circuit pattern 320 (e.g., the first circuit pattern 322, the second circuit pattern 324, and/or the circuit through connector 326).

In an embodiment, the first separated pattern 332 may be formed by the same process as the first circuit pattern 322. Thereby, the first separated pattern 332 and the first circuit pattern 322 may include the same material, and may be disposed on the same layer. The first separated pattern 332 and the first circuit pattern 322 may have the same thickness, cross-sectional structure, or stacking structure.

In an embodiment, the second separated pattern 334 may be formed by the same process as the second circuit pattern 324. Thereby, the second separated pattern 334 and the second circuit pattern 324 may include the same material, and may be disposed on the same layer. The second separated pattern 334 and the second circuit pattern 324 may have the same thickness, cross-sectional structure, or stacking structure.

In some embodiments, the second circuit pattern 324 and the second separated pattern 334 may be formed by the same process as a process of forming the first circuit pattern 322 and the first separated pattern 332. Thereby, the second circuit pattern 324 and the second separated pattern 334 may include the same material as the first circuit pattern 322 or the first separated pattern 332. The second circuit pattern 324 and the second separated pattern 334 may have the same thickness, cross-sectional structure, or stacking structure as the first circuit pattern 322 or the first separated pattern 332.

In some embodiments, the second circuit pattern 324 and the second separated pattern 334 may be formed by a process different from a process of forming the first circuit pattern 322 and the first separated pattern 332. Accordingly, the second circuit pattern 324 and the second separated pattern 334 may include the same material as the first circuit pattern 322 or the first separated pattern 332, or may include a different material from the first circuit pattern 322 or the first separated pattern 332. The second circuit pattern 324 and the second separated pattern 334 may have the same thickness, cross-sectional structure, or stacking structure as the first circuit pattern 322 or the first separated pattern 332, or may have a different thickness, cross-sectional structure, or stacking structure from the first circuit pattern 322 or the first separated pattern 332.

The circuit through connector 326 may be formed by the same process as a process of forming the through connector 336. For example, a first through hole for the through connector 336 and a second through hole for the circuit through connector 326 may be formed at the same time, and the first through hole and the second through hole may be filled with the same conductive material (e.g., metal) to form the through connector 336 and the circuit through connector 326. For example, the circuit through connector 326 may include or may be formed of at least one of copper (Cu), aluminum (Al), chromium (Cr), nickel (Ni), silver (Ag), molybdenum (Mo), gold (Au), titanium (Ti), or tantalum (Ta), or may include or may be formed of an alloy including those materials. The circuit through connector 326 and the through connector 336 may be formed by the same process as a process of forming the first conductive pattern 342 and/or the second conductive pattern 344. Various other modified embodiments are possible.

FIG. 20 is a cross-sectional view that illustrates a semiconductor module 100c according to an embodiment. The description of features the same as or substantially similar to features previously discussed above with respect to the semiconductor module 100a illustrated in, for example, FIG. 3, are omitted below for brevity.

Referring to FIG. 20, in an embodiment, a first separated pattern 332 may be electrically and/or physically connected to at least one (e.g. a ground pad 20g) of a plurality of pads 20p of a printed circuit board 20. A separated pattern 330 of a film package 30 may act as a ground electrode and a structure of the printed circuit board 20 may be simplified. Even when the separated pattern 330 is electrically connected to the printed circuit board 20, the separated pattern 330 may be electrically separated (e.g., isolated) or insulated from a circuit pattern 320.

In an embodiment, the first separated pattern 332 may be connected to the ground pad 20g of the printed circuit board 20 directly or through an adhesive layer 50. In FIG. 20, it is illustrated as an example that the adhesive layer 50 is disposed between the first separated pattern 332 and the ground pad 20g of the printed circuit board 20. The adhesive layer 50 may include or may be formed of a conductive adhesive material. For example, the adhesive layer 50 may include a the same material as a material of a first conductive adhesive layer 42 that electrically connects the pad 20p of the printed circuit board 20 and a first outer terminal, or may include a material different from the material of the first conductive adhesive layer 42.

However, the embodiments are not limited thereto, and the adhesive layer 50 may be omitted, and the first separated pattern 332 may be in contact with the ground pad 20g of the printed circuit board 20. For example, the first separated pattern 332 and the ground pad 20g of the printed circuit board 20 may be connected to each other by metal bonding. The ground pad 20g of the printed circuit board 20 may include the same metal as the first separated pattern 332. For example, the ground pad 20g of the printed circuit board 20 may include or may be formed of at least one of copper (Cu), aluminum (Al), chromium (Cr), nickel (Ni), silver (Ag), molybdenum (Mo), gold (Au), titanium (Ti), or tantalum (Ta), or may include or may be formed of an alloy including those materials. For example, the first separated pattern 332 and the ground pad 20g of the printed circuit board 20 may include or may be formed of copper, and the film package 30 and the printed circuit board 20 may be bonded (e.g., directly bonded) to each other by copper-to-copper bonding. Thereby, material cost may be reduced and a heat dissipation property may be enhanced more.

FIG. 21 is a cross-sectional view that illustrates a semiconductor module 100d according to an embodiment. The description of features the same as or substantially similar to features previously discussed above with respect to the semiconductor module 100a illustrated in, for example, FIG. 3, are omitted below for brevity.

Referring to FIG. 21, in an embodiment, a first thickness T1 of a first conductive pattern 342 and a second thickness T2 of a second conductive pattern 344 may be different from each other. For example, the first thickness T1 of the first separated pattern 332 and the second thickness T2 of the second separated pattern 334 may be different from each other. The first circuit pattern 322 and the first separated pattern 332 may have the same first thickness T1. Even though a second circuit pattern is omitted in FIG. 21, when the second circuit pattern is included, the second circuit pattern and the second separated pattern 334 may have the same second thickness T2.

For example, the second thickness T2 of the second conductive pattern 344 may be greater than the first thickness T1 of the first conductive pattern 342. Thereby, the second separated pattern 334 that has an area greater than an area of the first separated pattern 332 has the second thickness T2, which is relatively large, and a volume of the second separated pattern 334 may increase. Accordingly, a heat dissipation property may be largely enhanced through the second separated pattern 334. However, the embodiments are not limited thereto, and the second thickness T2 of the second conductive pattern 344 may be less than the first thickness T1 of the first conductive pattern 342.

The film package 30 that includes the first separated pattern 332 and the second separated pattern 334 having different thicknesses may be formed by any of various methods.

For example, a through hole may be formed at the base film 310, and a seed layer may be formed.

Subsequently, the first conductive pattern 342 that includes the first circuit pattern 322 and the first separated pattern 332 may be formed on the first surface 311 of the base film 310, and the second conductive pattern 344 that includes the second circuit pattern and/or the second separated pattern 334 may be formed on the second surface 312 of the base film 310. For example, with respect to the first surface 311 of the base film 310, a first photoresist pattern may be formed on the first surface 311 of the base film 310, a first metal layer may be formed, the first photoresist pattern may be removed, and a flash etching may be performed. With respect to the second surface 312 of the base film 310, a second photoresist pattern may be formed on the second surface 312 of the base film 310, a second metal layer may be formed, the second photoresist pattern may be removed, and a flash etching may be performed.

An order of processes (e.g., a process of forming a first photoresist layer, an exposure process, a developing process, a process of forming the first metal layer, a process of removing the first photoresist pattern, and the flash etching process) with respect to the first surface 311 of the base film 310 and an order of processes (e.g., a process of forming a second photoresist layer, an exposure process, a developing process, a process of forming the second metal layer, a process of removing the second photoresist pattern, and the flash etching process) may be variously modified.

In some embodiments, the processes with respect to the second surface 312 of the base film 310 may be performed after the processes with respect to the first surface 311 of the base film 310 are performed, or the processes with respect to the first surface 311 of the base film 310 may be performed after the processes with respect to the second surface 312 of the base film 310 are performed.

In some embodiments, at least a part of the processes with respect to the second surface 312 of the base film 310 and at least a part of the processes with respect to the first surface 311 of the base film 310 may be performed together in the same process. For example, the process of forming the first photoresist layer and the process of forming the second photoresist layer may be performed in the same process, the process of removing the first photoresist pattern and the process of removing the second photoresist pattern may be performed in the same process, and/or the flash etching process may be performed in the same process. Various other modified embodiments are possible.

Subsequently, a protective layer 350 may be formed, a semiconductor chip 360 may be mounted, and a molding portion 364 may be formed.

While some examples have been described in connection with what is presently considered to be some practical embodiments, it is to be understood that the disclosure is not limited to the disclosed embodiments, and that the disclosure is intended to cover various modifications and equivalent arrangements included within the spirit and scope of the appended claims.

What is claimed is:

1. A semiconductor module, comprising:
a film package; and
a printed circuit board connected to a first surface of the film package,
wherein the film package comprises:
a base film;
a semiconductor chip on the first surface of the base film; and
a first conductive pattern on the first surface of the base film,
wherein the first conductive pattern includes a first circuit pattern and a first dummy pattern, and
wherein the first dummy pattern is spaced apart from the first circuit pattern and is between the first surface of the base film and the printed circuit board.

2. The semiconductor module of claim 1, wherein the first circuit pattern includes a first outer terminal and a second outer terminal,
wherein the first outer terminal is adjacent to a first end of the film package in a first direction,
wherein the second outer terminal is adjacent to a second end of the film package, the second end of the film package being opposite to the first end of the film package in the first direction, and
wherein the first outer terminal is disposed between the first dummy pattern and the first circuit pattern.

3. The semiconductor module of claim 2, wherein the first outer terminal and the second outer terminal each include a plurality of individual conductive layers having an elongated shape,
wherein a line width, or a pitch, or an interval of the plurality of the individual conductive layers included in the first outer terminal is greater than a line width, or a pitch, or an interval of the plurality of the individual conductive layers included in the second outer terminal; or
wherein, in the first direction, a distance between the semiconductor chip and the second outer terminal is greater than a distance between the semiconductor chip and the first outer terminal.

4. The semiconductor module of claim 1, wherein the first dummy pattern is electrically isolated from the first circuit pattern, and
wherein the first dummy pattern forms a heat dissipation path to the printed circuit board.

5. The semiconductor module of claim 1, wherein the first dummy pattern is directly connected to the printed circuit board or is connected to the printed circuit board via an adhesive layer.

6. The semiconductor module of claim 1, wherein the first dummy pattern includes the same material as a material of the first circuit pattern and is on the same layer as the first circuit pattern.

7. The semiconductor module of claim 1, further comprising:
a circuit region where the first circuit pattern is disposed and a dummy region where the first dummy pattern is disposed; and
a second dummy pattern on a second surface of the base film, the second surface of the base film being opposite to the first surface of the base film and vertically overlapping at least a portion of the dummy region.

8. The semiconductor module of claim 7, further comprising:
a through connector penetrating the base film and connected to the first dummy pattern and the second dummy pattern in the dummy region.

9. The semiconductor module of claim 7, wherein the second dummy pattern vertically overlaps at least a portion of the circuit region.

10. A display device, comprising:
a film package;
a printed circuit board connected to the film package; and
a display panel connected to the film package,
wherein the film package includes a base film, a semiconductor chip on a first surface of the base film facing the printed circuit board or the display panel, and a first conductive pattern on the first surface of the base film,
wherein the first conductive pattern includes a first circuit pattern and a first dummy pattern, and
wherein the first dummy pattern is spaced apart from the first circuit pattern and is between the first surface of the base film and the printed circuit board.

11. A film package, comprising:
a base film;
a semiconductor chip on a first surface of the base film; and
a first conductive pattern on the first surface of the base film,
wherein the first conductive pattern comprises:
a first circuit pattern in a circuit region, wherein the first circuit pattern includes a first outer terminal at a first end of the circuit region in a first direction and a second outer terminal at a second opposite end of the circuit region in the first direction, and
a first dummy pattern in a dummy region outside the circuit region in the first direction and electrically isolated from the first circuit pattern and the semiconductor chip.

12. The film package of claim 11, wherein the first outer terminal is disposed between the dummy region and the first end of the circuit region.

13. The film package of claim 12, the first outer terminal and the second outer terminal each include a plurality of individual conductive layers having an elongated shape,
wherein a line width, or a pitch, or an interval of the plurality of the individual conductive layers included in the first outer terminal is greater than a line width, or a pitch, or an interval of the plurality of the individual conductive layers included in the second outer terminal; or
wherein, in the first direction, a distance between the semiconductor chip and the second outer terminal is greater than a distance between the semiconductor chip and the first outer terminal.

14. The film package of claim 11, wherein the first dummy pattern includes the same material as a material of the first circuit pattern and is on the same layer as the first circuit pattern.

15. The film package of claim 11, comprising:
a second dummy pattern on a second surface of the base film, the second surface of the base film being opposite to the first surface of the base film and vertically overlapping at least a portion of the dummy region.

16. The film package of claim 15, further comprising:
a through connector penetrating the base film and connected to the first dummy pattern and the second dummy pattern in the dummy region.

17. The film package of claim 15, wherein the second dummy pattern vertically overlaps at least a portion of the circuit region.

18. The film package of claim 11, wherein the first dummy pattern is disposed to have an asymmetrical shape in the first direction.

19. The film package of claim 11, wherein the first dummy pattern has a line shape or a bar shape extending in a second direction that intersects the first direction.

20. The film package of claim 11, wherein a first width of the first dummy pattern in the first direction is greater than a width of the first outer terminal or a width of the second outer terminal in the first direction; or
wherein the first width of the first dummy pattern in the first direction is greater than a distance between the semiconductor chip and the first outer terminal in the first direction.
